(19) United States
(12) Patent Application Publication
(10) Pub. No.: US 2006/0189129 A1
(43) Pub. Date: Aug. 24, 2006

(54) Method for applying metal features onto barrier layers using ion permeable barriers

(75) Inventors: Rajesh Baskaran, Kalispell, MT (US); Bioh Kim, Kalispell, MT (US); Robert W. Batz JR., Kalispell, MT (US); Tom L. Ritzdorf, Bigfork, MT (US); John L. Klocke, Kalispell, MT (US); Kyle M. Hanson, Kalispell, MT (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Semitool, Inc., Kalispell, MT (US)

(21) Appl. No.: 11/413,228

(22) Filed: Apr. 28, 2006

Related U.S. Application Data
(63) Continuation-in-part of application No. 10/470,287, filed on Jul. 22, 2003.
(63) Continuation-in-part of application No. 10/861,899, filed on Jun. 3, 2004.
Application No. 10/861,899 is a continuation-in-part of application No. 09/872,151, filed on May 31, 2001.
(63) Continuation-in-part of application No. 10/729,357, filed on Dec. 5, 2003.
(63) Continuation-in-part of application No. 10/729,349, filed on Dec. 5, 2003.
Application No. 10/729,349 is a continuation-in-part of application No. 10/059,907, filed on Jan. 29, 2002.
Application No. 10/059,907 is a division of application No. 09/531,828, filed on Mar. 21, 2000, now Pat. No. 6,368,475.

(51) Int. Cl. C25D 5/34; H01L 21/44

(52) U.S. Cl. 438/652; 438/677; 205/219

(57) ABSTRACT

The methods described are directed to processes for producing structures containing metallized features for use in microelectronic workpieces. The processes treat a barrier layer to promote the adhesion between the barrier layer and the metallized feature. Suitable means for promoting adhesion between barrier layers and metallized features include an acid treatment of the barrier layer, an electrolytic treatment of the barrier layer, or deposition of a bonding layer between the barrier layer and metallized feature. The processes described modify an exterior surface of a barrier layer making it more suitable for electrodeposition of metal on a barrier, thus eliminating the need for a PVD or CVD seed layer deposition process. According to the processes described metallized features are formed on the treated barrier layers using processes that employ ion permeable barriers.

### CROSS-REFERENCE TO RELATED APPLICATION

This application is a continuation-in-part of application Ser. No. 10/470,287, filed Jul. 22, 2003, which claims the benefit of Provisional Application No. 60/347,520, filed Jan. 10, 2002, and is a continuation-in-part of application Ser. No. 10/861,899, filed Jun. 3, 2004, which in turn is a continuation-in-part of application Ser. No. 09/872,151, filed May 31, 2001, which claims the benefit of Provisional Application No. 60/129,055, filed Apr. 13, 1999; and is a continuation-in-part of application Ser. No. 10/729,357, filed Dec. 5, 2003, and is a continuation-in-part of application Ser. No. 10/729,349, filed Dec. 5, 2003. This application also is a continuation-in-part of application Ser. No. 10/059,907, filed Jan. 29, 2002, which in turn is a divisional application of application Ser. No. 09/531,828, filed Mar. 21, 2000, now Pat. No. 6,368,475.

### FIELD OF THE INVENTION

The present invention is directed to methods for forming metallized structures on barrier layers through electrochemical deposition.

### BACKGROUND OF THE INVENTION

In the fabrication of microelectronic devices, application of one or more metallization layers is an important step in the overall fabrication process. The metallization may be used in the formation of discrete microelectronic components, but is most often used to provide interconnect components formed on a workpiece, such as a semiconductor wafer. For example, metallized structures are used to interconnect devices of an integrated circuit.

An integrated circuit is an interconnected ensemble of devices formed within a semiconductor material and within a dielectric material that overlies a surface of the semiconductor. Devices that may be formed within the semiconductor include MOS transistors, bipolar transistors, diodes, and diffused resistors. Devices that may be formed within the dielectric include thin film resistors and capacitors. Typically, more than 100 integrated circuit die (IC chips) are constructed on a single 200 mm diameter silicon wafer. The devices utilized in each die are interconnected by conductor paths formed within the dielectric. Typically, two or more levels of conductor paths, with successive levels separated by a dielectric layer, are employed as interconnections. Aluminum alloy and silicon oxide are examples of materials that have been used for conductive and dielectric features.

With the continuing interest by integrated circuit manufacturers for ways to reduce delays in the propagation of electrical signals, copper has replaced aluminum alloy as the material of choice for interconnect structures.

In addition to its desirable electrical properties, the use of copper as interconnect structures allows integrated circuit manufacturers to leverage electrodeposition process advantages provided by the use of copper. For example, electrodeposition of copper currently provides the most cost-effective manner in which to deposit a copper metallization layer. In addition to being economically viable, electrodeposition techniques provide substantially conformal copper films that are mechanically and electrically suitable for interconnect structures.

Despite the advantages of copper, there are also difficulties in effectively and economically depositing copper metallization. For example, depositing copper metallization necessitates the need for the presence of barrier layer materials. The need for barrier layer materials arises from the tendency of copper to diffuse into silicon junctions and alter the electrical characteristics of the semiconductor devices formed in the substrate. Barrier layers made of, for example, titanium, titanium nitride, tantalum, tantalum nitride, tungsten, and tungsten nitride and the like are typically laid over the silicon junctions and any intervening layers prior to depositing a layer of copper. Unfortunately, materials used as barrier layers typically do not exhibit the electrical conductive properties necessary to allow for the uniform electrochemical deposition of copper directly onto the barrier layers using conventional gap fill chemistries and processes. Accordingly, current practice employs a conductive seed layer applied to the barrier layer before the workpiece is subjected to an electrochemical copper deposition process.

A number of processes for applying a conductive seed layer onto the barrier layer exist. One such process is chemical vapor deposition or CVD, in which a thin copper film is formed on the surface of the barrier layer by thermal decomposition and/or reaction of gas phase copper compositions. CVD can result in conformal copper coverage over a variety of topological profiles; however, CVD is expensive to carry out and utilizes expensive equipment.

Another known technique for depositing a seed layer onto the barrier layer is physical vapor deposition or PVD. PVD provides relatively good adhesion between the barrier layer and the deposit of copper seed layer when compared to a seed layer deposited by CVD. One disadvantage of PVD is that it may result in poor (nonconformal) step coverage when used to fill recessed micro-structures, such as vias and trenches, disposed in the surface of the semiconductor workpiece.

The need to deposit a seed layer using CVD or PVD as described above introduces a process step that requires a large capital investment in equipment to carry out the vapor deposition process. In addition, both PVD and CVD are considered to be relatively slow, thus adversely affecting manufacturing throughput.

Attempts have been made to electrodeposit copper directly onto a barrier layer of titanium nitride or titanium tungsten. However, it has been observed by the present inventors that electrochemical deposition of copper directly onto untreated barrier layers leads to unsatisfactory results, such as poor nucleation and copper peeling due to poor adhesion between the electrodeposited copper and the material of the barrier layer.

In certain electroplating processes, chelants or complexing agents are used to affect the electric potential at which metal ions are deposited onto microfeature workpieces. Other components that may be present in the processing of fluids include accelerators, suppressors, and levelers that can affect the results of an electroplating process. Although these types of materials can positively influence the electroplating process, their use is not without drawbacks. For example, it is possible for these components to have an adverse impact on the electrolytic process as a result of reactions or other interactions with electrodes used in the electrolytic process.

When depositing metals into narrow, deep trenches or vias, to line and completely fill the small features without creating voids or other nonuniformities in the deposited metal, a processing solution with a low conductivity is generally used. Such low conductivity processing fluids have relatively low hydrogen ion (H⁺) concentrations, i.e., relatively high pH. Suitable electrochemical processes for forming metal features using low conductivity processing fluids are disclosed in U.S. Pat. No. 6,197,181, which is herein incorporated by reference.

Electroplating using low conductivity/high pH processing fluids presents additional challenges. For example, inert anodes are generally required when high pH processing fluids are used because the high pH tends to passivate many types of consumable anodes. Such passivation may produce metal hydroxide particles and/or flakes that can adversely affect the quality of metal microfeatures deposited on the microelectronic workpiece. Use of inert anodes is not without its drawbacks. The present inventors have observed that when inert anodes are used, the resistivity of the deposited material increases significantly over a relatively small number of plating cycles. While this increase in the resistivity of the deposited material could be addressed by frequently changing the processing fluid, such a solution increases the operating cost of the plating process.

In view of the above, the inventors have recognized the need to provide processes for depositing metal features onto barrier layers that provide conformal metal coverage with adequate adhesion to the barrier layer, provide adequate deposition rates, are commercially viable, and which do not employ seed layers deposited by PVD or CVD. Suitable processes would also reduce adverse impacts created by the presence of complexing agents and/or other additives and also maintain deposit resistivity within desired ranges and during repeated plating cycles considered acceptable by microelectronic device manufacturers.

### BRIEF SUMMARY

The processes described herein are directed to processes for forming structures containing metallized features for use in microelectronic workpieces, wherein the metallized features are electrochemically deposited onto a barrier layer in the absence of a CVD or PVD deposited seed layer. The described processes allow integrated circuit manufacturers to reduce their costs and increase their throughput by avoiding expensive and time-consuming CVD or PVD methods for depositing seed layers. The described processes also reduce adverse impacts created by the presence of complexing and other additives in fluids used in the electrochemical deposition process.

Metallized structures produced by the processes described herein include a barrier layer formed adjacent to a substrate and an electrochemically deposited metallized feature adjacent the barrier layer, wherein the barrier layer has been treated as described herein. Suitable treatments for the barrier layer take a plurality of forms including treating the surface of the barrier layer with an acid (acid treatment), electrolytically treating the surface of the barrier layer, or electrochemically depositing an alloy on the surface of the barrier layer. In accordance with the processes described herein, exterior surfaces of the barrier layer treated as described herein have metal features electrochemically formed on the treated barrier layers through processes that use ion permeable barriers.

In one aspect of the processes described herein, a microelectronic workpiece including a barrier layer is provided. The barrier layer separates an underlying dielectric feature from metallized features that are to be formed on the barrier layer. As described in more detail below, the barrier layer is modified by electrolytically treating it before electrochemically depositing a metallized feature such as gap-fill metallization onto the treated barrier layer. By modifying the surface of the barrier layer, adhesion between the barrier layer and the electrochemically deposited metallized feature is improved and peeling of the deposited metallized feature from the barrier layer due to subsequent processing steps such as rinsing and drying is reduced or avoided. The metallized feature can be deposited onto the electrolytically treated surface of the barrier layer by contacting a portion of the electrolytically treated surface of the barrier layer with a first processing fluid that includes a cation, an anion, and a complexing agent. A counter electrode in contact with a second processing fluid is provided and an electrochemical reaction is produced at the counter electrode. During the metal deposition, movement of ionic species between the first processing fluid and the second processing fluid is substantially prevented.

In another aspect of the processes described herein, the barrier layer overlying a dielectric feature is modified by treating the surface of the barrier layer with an acid. The surface of the barrier layer after the acid treatment exhibits improved adhesion to a metallized feature subsequently deposited onto the surface of the barrier layer. The improved adhesion helps the subsequently deposited formed structure avoid delamination when it is subjected to subsequent processing steps such as rinsing and drying. A metallized feature can be deposited onto the acid treated surface of the barrier layer by contacting a portion of the acid treated surface of the barrier layer with a first processing fluid that includes a cation, an anion, and a complexing agent. A counter electrode in contact with a second processing fluid is provided and an electrochemical reaction is produced at the counter electrode. During the metal deposition, movement of ionic species between the first processing fluid and the second processing fluid is substantially prevented.

In another aspect, a barrier layer is modified by depositing an alloy of constant or varying composition onto the barrier layer using an electrochemical process. The alloy includes a first metal and a second metal where at least one of the metals forming the alloy is the same as the metal that comprises the metallized feature that is to be deposited on the alloy over the barrier layer. A metallized feature can be deposited onto the metal alloy by contacting a portion of the metal alloy with a first processing fluid that includes a cation, an anion, and a complexing agent. A counter electrode in contact with a second processing fluid is provided and an electrochemical reaction is produced at the counter electrode. During the metal deposition, movement of ionic species between the first processing fluid and the second processing fluid is substantially prevented.

The methods of the present invention can be used, in one instance, in microelectronic processing at any stage of processing where a barrier feature has been deposited and a metallized feature is desired to be formed thereon. The processes are useful in damascene and non-damascene architectures. Non-damascene architectures include those wherein the metallized features are provided through an additive process wherein the metal features are built up on a flat surface using photoresist and photolithography techniques.

The processes described herein provide an attractive alternative to processes that deposit seed layers using PVD or CVD. By avoiding the costs associated with PVD and CVD, integrated circuit manufacturers will be able to produce their products more cost-effectively. The present invention will also allow integrated circuit manufacturers to increase their throughput by avoiding time-consuming PVD or CVD used to deposit seed layers. By improving the adhesion between barrier layers and metallized features formed over the barrier layers, delamination between the metallized features and the barrier layer as a result of subsequent processing steps is reduced. By impeding the movement of ionic species between the first processing fluid in contact with the surface upon which a metallized feature is to be formed and a second processing fluid in contact with a counter electrode, adverse impacts due to the presence of complexing agents and other additives in the processing fluids are reduced while deposit properties (e.g., resistivity) are maintained within desired ranges over repeated plating cycles. Integrated circuit manufacturers will find these features desirable as they will increase production yields and produce more reliable devices.

### BRIEF DESCRIPTION OF THE DRAWINGS

The foregoing aspects and many of the attendant advantages of the apparatus's processes and structures described herein will become more readily appreciated as the same become better understood by reference to the following detailed description, when taken in conjunction with the accompanying drawings, wherein:

FIG. 1 shows a schematic illustration of a structure formed according to the processes described herein;

FIG. 2 shows a schematic flow sheet of a process described herein for forming a metallized feature on a barrier layer;

FIGS. 3-6 show a schematic illustration of a sequence of processing steps that includes a treatment of a barrier layer as described herein;

FIGS. 7-15 show a schematic illustration of a second sequence of processing steps that includes a treatment of a barrier layer as described herein;

FIG. 16 is a photo of an electrolytically deposited copper layer delaminating from a barrier layer that has not been treated as described herein;

FIG. 17 is a close-up view of a portion of the edge of the wafer of FIG. 16;

FIG. 18 is a photo of a copper layer electrolytically deposited onto a barrier layer acid treated as described herein;

FIG. 19 is a close-up view of a portion of the edge of the wafer of FIG. 18;

FIG. 20 is a photo of a copper layer electrolytically deposited onto a barrier layer electrolytically treated as described herein;

FIG. 21 is a close-up view of a portion of the edge of the wafer of FIG. 20;

FIG. 22 is a schematic illustration of a reactor for carrying out processes described herein using an anionic permeable barrier;

FIG. 23 is a schematic illustration of a reactor for carrying out processes described herein using a cationic permeable barrier;

FIG. 24 graphically illustrates deposit resistivity as a function of bath age for a deposit formed using processing fluids separated by an anion permeable barrier and a deposit formed using a processing fluid without an anion permeable barrier;

FIG. 25 is a schematic illustration of a chamber for carrying out processes described herein;

FIG. 26 is a schematic illustration of the chemistry and chemical reactions occurring in one embodiment of the processes for electroplating a metal described herein using an anion permeable barrier and an inert anode;

FIG. 27 is a schematic illustration of the chemistry and chemical reactions occurring in one embodiment of the processes for electroplating two metals described herein using an anion permeable barrier and an inert anode;

FIG. 28 is a schematic illustration of the chemistry and chemical reactions occurring in one embodiment of the processes for electroplating two metals described herein using an anion permeable barrier and a consumable anode;

FIG. 29 is a schematic illustration of the chemistry and chemical reactions occurring in one embodiment of the processes for electroplating a metal described herein using a cation permeable barrier and an inert anode;

FIG. 30 is a schematic illustration of the chemistry and chemical reactions occurring in one embodiment of the processes for electroplating a metal described herein using a cation permeable barrier and a consumable anode; and

FIG. 31 is a schematic illustration of a tool that includes chambers for carrying out processes described herein.

### DETAILED DESCRIPTION

A basic understanding of certain terms used herein will assist the reader in understanding the disclosed subject matter. To this end, definitions of certain terms, as used herein, are set forth below.

As used herein, the terms “microfeature workpiece” or “workpiece” refer to substrates on and/or in which microdevices are formed. Such substrates include semiconductive substrates (e.g., silicon wafers and gallium arsenide wafers), nonconductive substrates (e.g., ceramic or glass substrates), and conductive substrates (e.g., doped wafers). Examples of microdevices include microelectronic circuits or components, micromechanical devices, microelectromechanical devices, micro-optics, thin film recording heads, data storage elements, microfluidic devices, and other small scale devices.

As used herein, the term “substrate” refers to a base layer of material over which one or more metallization levels is disposed. The substrate may be, for example, a semiconductor, a ceramic, a dielectric, etc.

As used herein, “barrier layer” is used to denote any feature that acts to prevent the migration of metals or any other material to or from a conducting region to or from a non-conducting region of the microelectronic workpiece.

The processes described herein are directed to processes for forming metallized structures for microelectronic workpieces that include a barrier layer formed on an underlying substrate, such as on a semiconductor material or a dielectric material. The metallized structures thus have applicability to diverse classes of microelectronic components and/or interconnects. In accordance with processes described herein, metallized features are formed by a process that includes a step of modifying a barrier layer so as to improve the adhesion between the barrier layer and a metallized feature electrochemically deposited on the barrier layer and reduces the adverse impacts created by the presence of complexing agents and/or other additives. A structure formed in accordance with processes described herein is described below, followed by a description of several embodiments of processes for forming metallized structures. In the description that follows regarding electroplating a metal onto a treated barrier layer, specific reference is made to copper as an example of a metal ion that can be electroplated onto a treated barrier layer. The reference to copper ions is for exemplary purposes, and it should be understood that the following description is not limited to copper ions. Examples of other metal ions useful in processes described herein include gold ions, tin ions, silver ions, platinum ions, lead ions, cobalt ions, zinc ions, nickel ions, ruthenium ions, rhodium ions, iridium ions, osmium ions, rhenium ions, and palladium ions. In the descriptions that follow regarding electroplating more than one metal onto a treated barrier layer, specific reference is made to a tin-silver solder system as an example of metal ions that can be electroplated onto a treated barrier layer to form a composite deposit. The reference to deposition of tin-silver solder is for exemplary purposes, and it should be understood that the reference to tin-silver solder is not intended as an indication that the description below is limited to tin-silver solder systems.

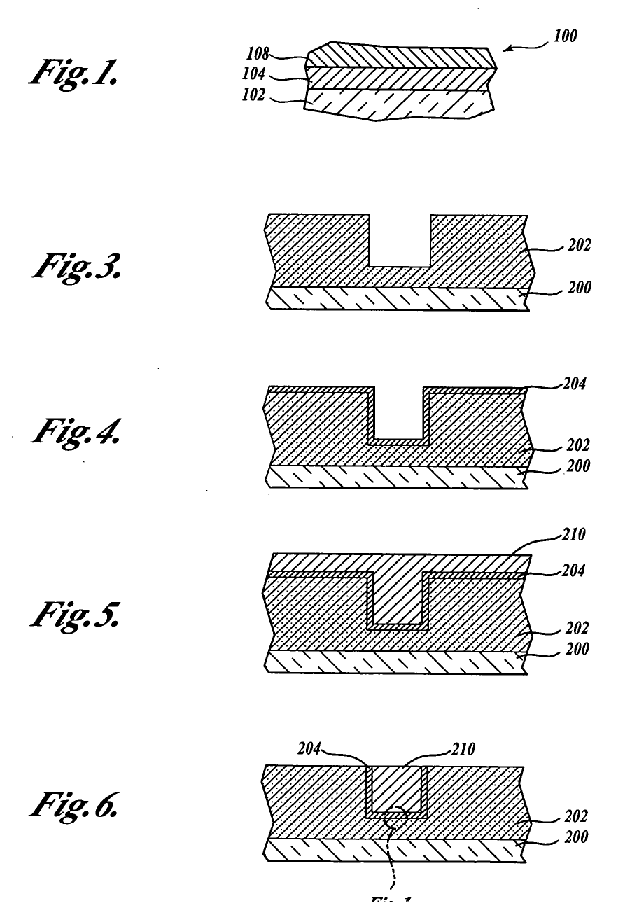

FIG. 1 illustrates a metallized structure 100 formed in accordance with processes described herein. Structure 100 is useful in the manufacture of microelectronic workpieces containing a plurality of devices, wherein such devices are capable of utilizing structure 100 for interconnects between the devices. Structure 100 can form the bottom of an interconnect and/or the sides of metallized features, such as would be the case in recessed features. Typical interconnect features are submicron in size, for example, 30 to 500 nanometers. Structure 100 includes a substrate 102 and a barrier layer 104 disposed exterior to substrate 102. Disposed exterior to barrier layer 104 is metallized feature 108.

As described above, substrate 102 is typically a dielectric, the composition of which is generally dependent on the function of the metallized structure 100. When the metallized structure 100 is used to implement a post or line of an electrical interconnect network, dielectric layer 102 is preferably comprised of a low-k material. When the metallized structure is used to implement a discrete microelectronic component such as a capacitor, however, the dielectric layer 102 is preferably comprised of a high-k material.

Barrier layer 104 is useful to prevent diffusion or migration of atoms from metallized feature 108 into dielectric 102. Suitable materials for forming barrier layer 104 include, but are not limited to titanium, titanium nitride, titanium silicon nitride (TiSiN), tantalum, tantalum nitride, or tantalum silicon nitride (TaSiN). Barrier layer 104 can be deposited by any of the various known techniques, such as CVD, PVD, or atomic layer chemical vapor deposition. The particular process chosen to deposit the barrier layer will depend upon the particular material being used to form the barrier layer. Exemplary thicknesses for a barrier layer are 10-100 nanometers.

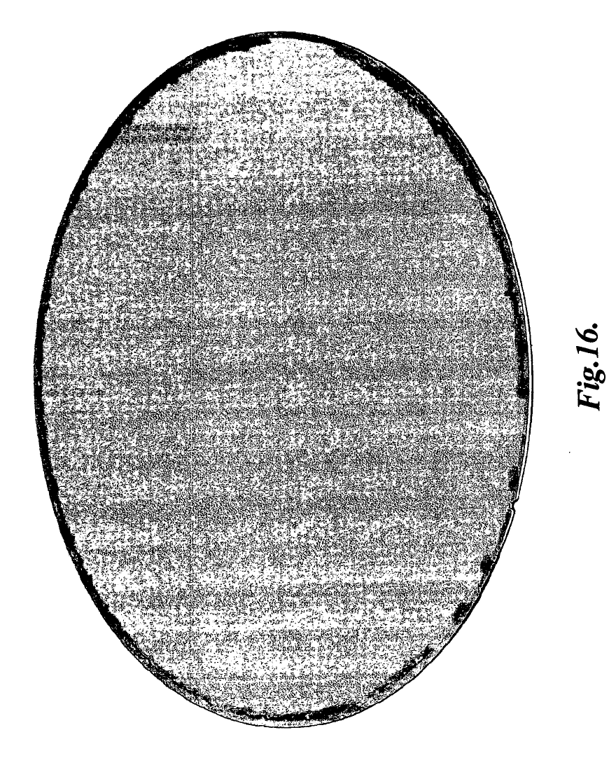

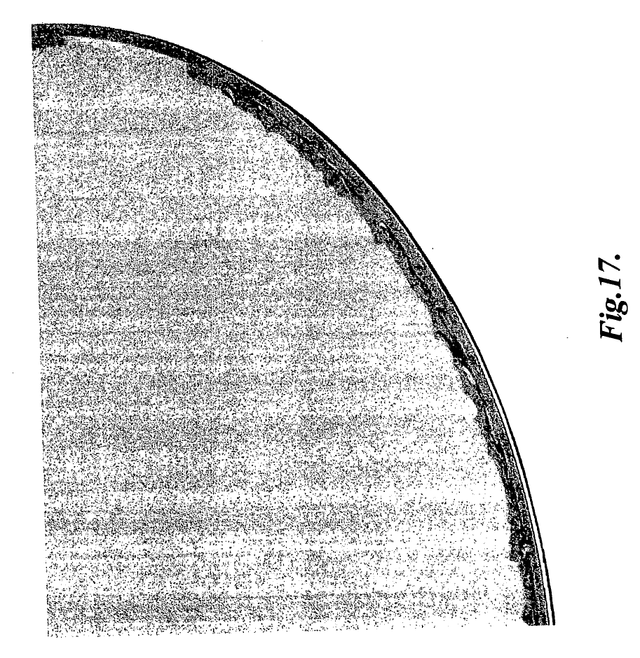

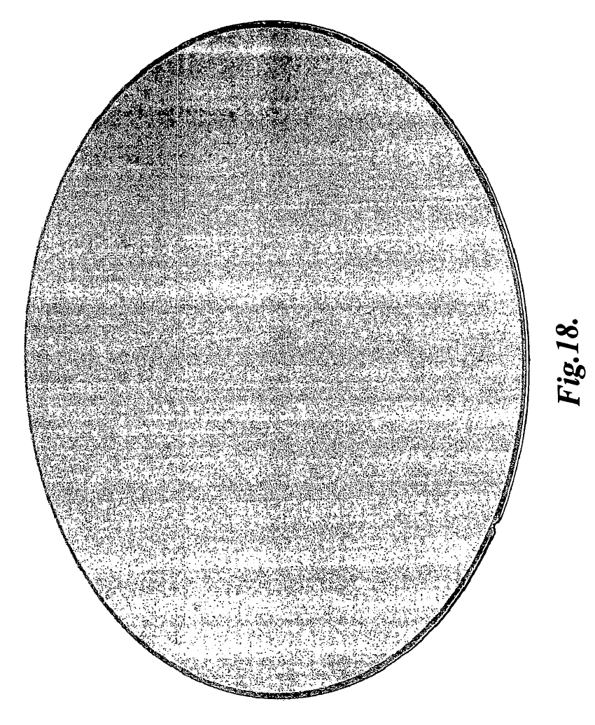

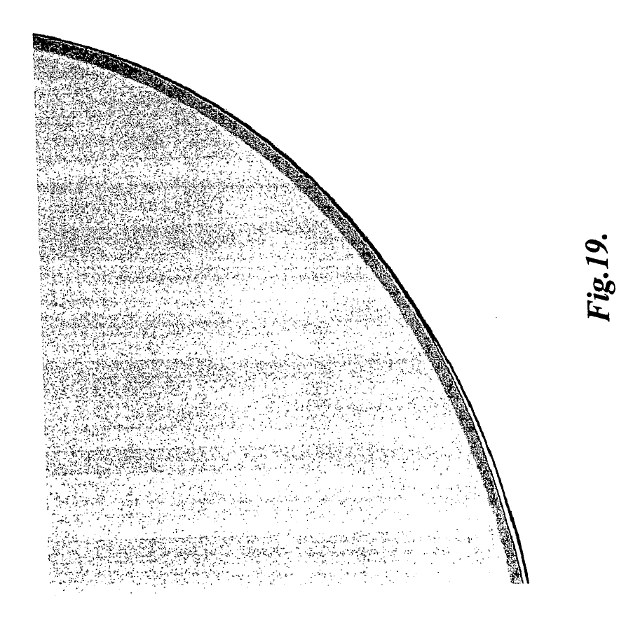

As discussed in the background, the present inventors have observed that attempting to electrolytically deposit copper directly onto an untreated barrier layer results in less than satisfactory results, particularly from the standpoint of the adhesion between barrier layer 104 and metallized structure 108. FIGS. 16 and 17 are photographs of a wafer with copper plated directly onto an untreated tantalum barrier layer, followed by rinsing and drying. In contrast, FIGS. 18 and 19 are photographs of a wafer with copper electrolytically deposited directly onto a tantalum barrier layer subjected to an acid treatment as described below in more detail by rinse and dry steps. The wafer in FIGS. 18 and 19 shows copper present on the whole surface of the wafer without any substantial peeling or debonding evident. In contrast, the wafer shown in FIGS. 16 and 17 exhibits copper peeling and bonding near the edges of the wafer.

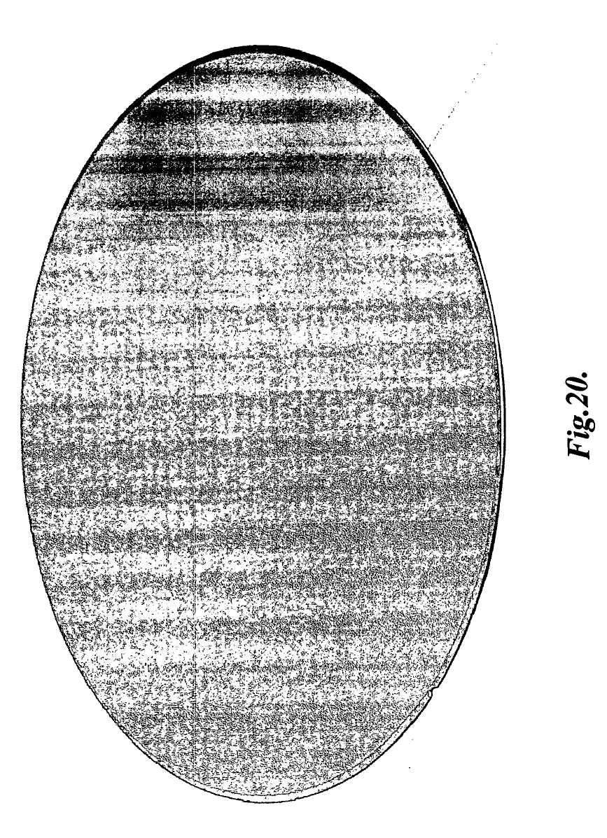

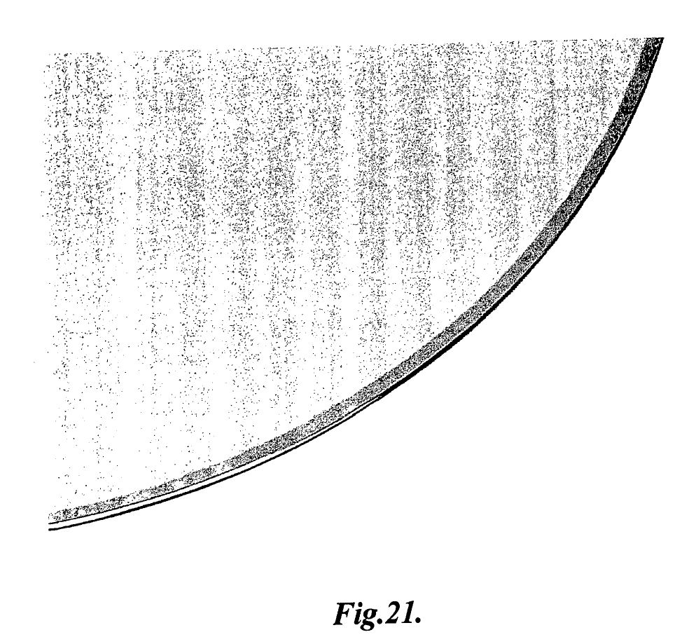

FIGS. 20 and 21 are photographs of a wafer with copper electrolytically deposited directly onto a tantalum barrier layer subjected to a cathodic electrolytic treatment as described below in more detail. After rinsing and drying, there is no evidence of substantial peeling or debonding of the copper layer on the wafer of FIGS. 20-21.

The deposited copper in FIGS. 18-21 appears smooth and dense compared to the copper layer of FIGS. 16-17. A comparison of these figures provides a qualitative measure of the impact of acid treating and electrolytically treating a barrier layer prior to direct electrolytic deposition of copper onto the barrier layer.

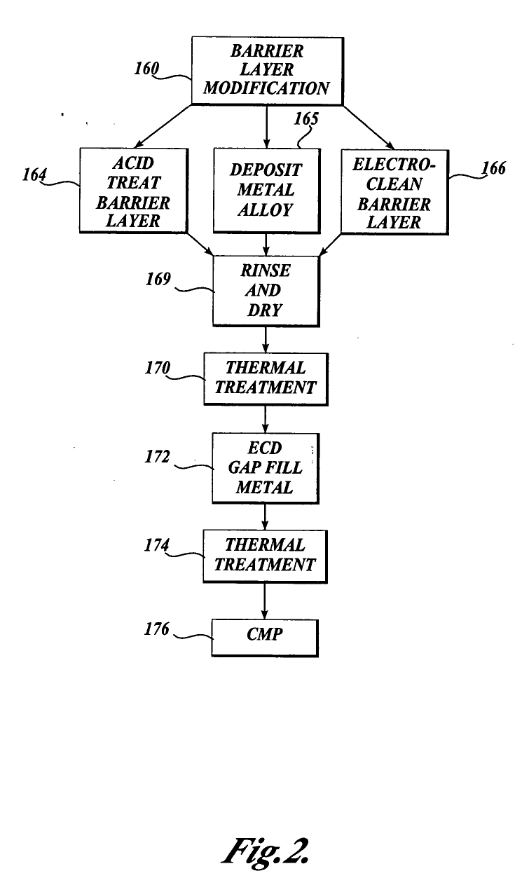

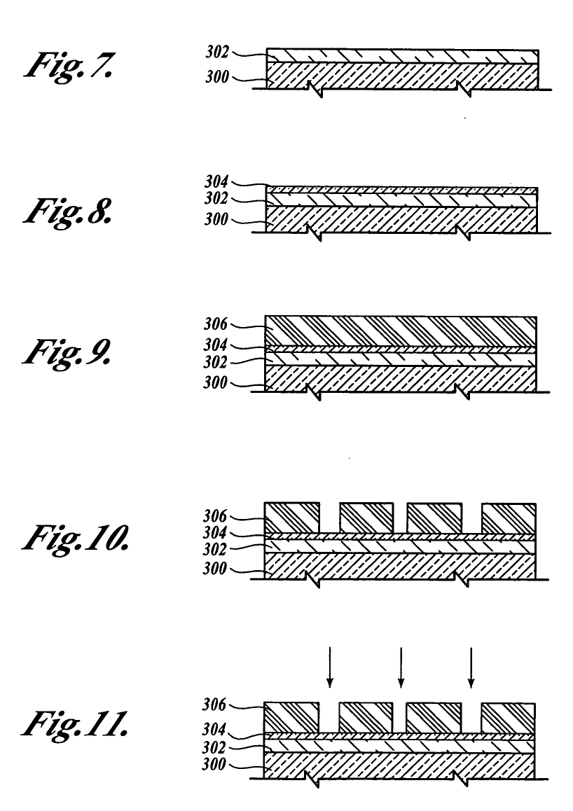

Referring to FIGS. 2-6, a processing sequence for forming metallized features incorporating processes described herein is illustrated. It should be readily apparent that a dielectric structure 202 and a barrier layer 204 have been provided on a substrate 200 prior to the barrier layer modification step identified in block 160 of FIG. 2. As mentioned above, barrier layer 204 is subjected to an acid treatment step 164, or an electrolytic treatment step 166. Once barrier layer 204 has been subjected to the acid treatment or the electrolytic treatment, metallized feature 210 can be deposited electrochemically, preferably electrolytically onto the treated barrier layer at 172. Examples of metallized feature 210 include a seed layer or gap fill metallization. A non-limiting example of a suitable material for the metallized feature is copper. While copper is a suitable low resistivity material, other suitable materials as described above including noble metals or their alloys can be used to form the metallized features on a microelectronic workpiece.

Continuing to refer to FIGS. 2-6, following the treatment of the barrier layer, the surface of the microelectronic workpiece carrying the dielectric, and treated barrier layer, may be electroplated (optional) at block 168 with a metal or metal-alloy. The deposited metal film may be rinsed and dried at block 169.

After the rinsing and drying, the substrate and treated barrier layer can be subjected to a thermal processing step 170, whereby the plated metal film and treated barrier layer are held at an elevated temperature for a period of time. This thermal treatment step 170 should not be carried out before the rinsing and drying step 169 because the surface of the treated barrier layer and/or metal film may contain remnants of the deposition bath on its surface. These drops of solution adhering to the freshly barrier layer or deposited metal layer need to be removed by rinsing with deionized water and then drying the wafer to remove water droplets. The rinse and dry steps are important; without these two steps, bath solution droplets left on the wet wafer surface can crystallize and cause particle problems if thermally treated. The thermal treatment facilitates more robust bonding between the deposited metal-film and the underlying barrier layer, (or optionally prepares the barrier surface for subsequent electrodeposition). Following optional thermal treatment step at 170, metallized features such as a seed layer or gap-fill metal can be deposited at block 172. The metallization step 172 may be followed by a second rinse and dry step 173 which is then followed by a second thermal treatment step at block 174. As noted above, deposition of metal at block 168 may form seed layers, gap-fill metallization and/or conformally line larger features. When seed layers are formed at block 172, the substrate carrying the deposited seed layers can be rinsed and dried at block 173 followed by a thermal treatment at block 174. The thermally treated seed layer can then be subjected to gap-fill metallization at block 175 followed by rinsing and drying at block 177 and thermal treatment at block 178. Following the thermal treatment at block 178, depending on the architecture employed, a chemical mechanical polishing step 176 can take place, if required, to remove unwanted portions of barrier layer 204 and metallized feature 210. The deposition of metal at block 172 may include seed layer repair deposition and metal gap-fill deposition occurring simultaneously), while conformally lining larger features. The aforementioned sequence of processing steps may be repeated to form further levels containing any number of metallized features.

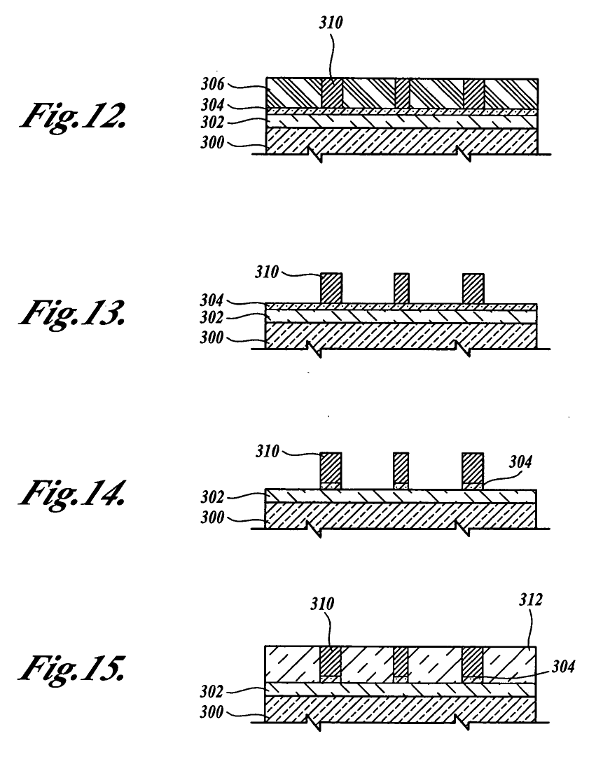

Referring to FIGS. 7-15, a further non-limiting example of a workpiece formation process wherein processes described herein may be utilized is schematically depicted.

In FIG. 7, a substrate 300 is provided and a dielectric layer 302 is applied over the substrate 300. A suitable barrier layer 304 is applied to the dielectric layer 302 in a blanket process, as illustrated in FIG. 8. Referring now to FIG. 9, a photoresist 306 is deposited on the barrier layer 304. Deposition of photoresist 306 can take place according to any well-known technique. In FIG. 10, conventional photolithographic techniques are applied to the photoresist to provide the desired negative of the metallized features to be formed in subsequent steps.

Referring to FIG. 11, in accordance with one aspect of the processes described herein, as described below in more detail, the exposed portions of barrier layer 304 are treated in one of several ways. As discussed below, such treatments include electrolytically treating or acid treating the exposed surface of barrier layers 304 or depositing a bonding layer onto the exposed portions of barrier layer 304. When the exposed portions of barrier level 304 are acid treated or electrolytically treated, the electrolyte bath or acid solution should be chosen so as not to adversely affect the photoresist or other features on the workpiece surface.

Referring now to FIG. 12, after treating the barrier layer 304 using a process described herein, electrodeposition of the metallized feature 310 can take place to complete the metallized feature in a manner described below in more detail. While not shown in the FIGS. 7-15, in some aspects of the processes described herein, it may be advantageous before bulk deposition occurs, to provide an electrolytically deposited metal seed layer. The metallized feature 310, whether it be a metal seed layer or bulk metal feature, advantageously adheres to the treated surface of barrier layer 304 without the need for a PVD or CVD seed layer.

Referring now to FIG. 13, photoresist 306 present in FIG. 12 has been stripped using conventional techniques to further expose the metal structures. Referring to FIG. 14, those portions of barrier layer 304 exposed by removal of photoresist 306 are removed. In certain instances, removal of the exposed portions of barrier layer 304 may require that steps be taken to protect those portions of the exposed deposited metal structure. For example, isolating the exposed portions of metallized feature 310 from the conditions used to remove the exposed portions of barrier layer 304. In FIG. 15, a dielectric material 312 is applied to the workpiece to encapsulate the metal structures. The aforementioned sequence of processing steps may be repeated to form further levels containing any number of metallized features.

While representative examples of sequences of processing steps have been presented above, the processes described herein are useful in other processing schemes that include different steps for producing metallized features on a microelectronic workpiece.

Without being bound by theory, the acid or electrolytic treatment of the barrier layers described herein is believed to remove natural oxides that form on the surface of the barrier layer, or convert them to more desirable species. In addition, it is believed that the acid or electrolytic treatment increases the number of activation sites on the surface of the barrier layer where nucleation of the metals comprising the metallized feature can occur. The acid and electrolytic treatments are described below in more detail.

Acid Treatment

In accordance with one aspect of the processes described herein, barrier layer 104 is treated by contacting the exterior surface of the barrier layer 104 with an acid solution. The acid solution need not contain metal ions that are readily deposited onto the barrier layer. If the bath includes metal species that readily deposit onto the barrier layer, such deposition can be avoided by contacting the barrier layer 104 with the solution in the absence of electrical power.

The acid treatment of the barrier layer 104 can be carried out in an aqueous solution containing an acid. The selection of a specific acid and its concentration will depend in part upon the particular material of the barrier layer. Selection of an appropriate acid should take into consideration factors such as selectivity of acid for the barrier layer material, effect of acid on other features, aggressiveness of acid toward barrier layer material and compatibility of the acid with the overall workpiece processing sequence. One suitable bath is an aqueous solution having a nitric acid concentration up to about 50 weight %. An aqueous solution of nitric acid containing about 20-30 weight % nitric acid is particularly suitable for treating titanium nitride barrier layers.

Hydrofluoric acid is another suitable acid for treating barrier layers in accordance with the present invention. When hydrofluoric acid is used as a treating acid for tantalum barrier layers, aqueous solutions having hydrofluoric acid concentrations less than about 5 weight % are suitable. Such solutions may incorporate wetting agents/surfactants at parts per million concentration levels. Hydrofluoric acid concentrations below about 5 weight % are desired in order to etch the barrier layer at an acceptable rate. At concentrations of 5 weight % and above, the rate that hydrofluoric acid etches the barrier layer makes it difficult to accurately control the degree of the etching. In addition, at lower acid concentrations the effect of the loss of acid from solution due to vaporization of the acid is lower compared to the effect of vaporization from solutions having a higher acid concentration. By minimizing the degree to which the concentration of acid in the treating solution changes over time, the consistency and repeatability of the treatment from wafer to wafer is maximized. In addition, lowering the loss of acid from solution due to vaporization results in less chemical consumption and waste, which provides a cost savings and an environmental benefit. Other useful acids include hydrochloric, methane-sulfonic, and sulfuric.

The acid solution can be contacted with the barrier layer for varying amounts of time. The length of the contact will vary depending upon the material comprising the barrier layer, as well as the concentration of the acid in the solution. Shorter times are preferred in order to increase throughput. Contact times on the order of 10 to 25 seconds are exemplary, although longer times may be necessary and shorter times may provide satisfactory results.

An exemplary acid treatment for a tantalum barrier layer employs an aqueous solution containing about 2 weight % hydrofluoric acid and is carried out in a conventional spray chamber. When the workpiece includes a silicon wafer, spraying treatment solutions on the surface of the wafer is preferred, as opposed to dipping the wafer into the acidic treatment solutions, in order to avoid degradation of the silicon (present on the backside of the wafer) by the acid solution. The acid treatment generally involves steps of applying the acid to the surface of the workpiece followed by rinsing and removal of the rinsing solution.

An exemplary sequence of steps includes rinsing the surface of the wafer carrying the barrier layer with deionized water for about 15 seconds at a wafer rotation rate of about 50 rpms. The hydrofluoric acid solution can then be sprayed onto the surface of the wafer for 15 seconds with the wafer rotating at about 150 rpms. Following the acid treatment, the surface of the wafer is rinsed with deionized water for 15 seconds while rotating at about 250 rpms. Following termination of the deionized water rinse, the wafer is spun for about 5 seconds at about 250 rpms in order to remove the large water droplets from the surface of the wafer. The wafer is then wet-transferred to a plating chamber where a metallized feature can be electroplated onto the barrier layer as described below in more detail.

Electrolytic Treatment

In this aspect of the processes described herein, the surface of barrier layer 104 is modified by electrolytically treating the exterior surface of the barrier layer 104 in an alkaline or acid solution.

In one instance, the barrier layer serves as a cathode and undergoes cathodic treatment with an inert anode, such as platinum, in a suitable reactor or chamber. Optionally, the barrier layer can undergo an anodic treatment to provide a barrier layer that adheres more strongly to the subsequently deposited metal compared to the adhesion between an untreated barrier layer and a deposited metal. Additionally, a combination of cathodic treatment followed by a mild anodic treatment of the barrier layer may be employed.

Metallized features that are electrochemically deposited on barrier layers that have been modified through this electrolytic treatment exhibit improved uniformity and adhesion of the metallized features to the barrier layer compared to metallized features that are deposited onto untreated barrier layers. Without intending to be bound by theory, it is believed the cathodic treatment converts native oxides on the surface of the barrier layer to other species (e.g., metal hydrides M-H), leaving a barrier layer surface that is more suitable for receiving and adhering metallized features deposited by a subsequent electrochemical process.

As noted above, an anodic treatment can follow the cathodic treatment. It is believed that the anodic treatment produces a metal oxide layer on the barrier that contributes to the adhesion between the barrier layer and the metallized feature deposited on the barrier layer. Some barrier layer materials are naturally more suited to treatment using the cathodic and anodic treatment rather than a cathodic treatment alone. One consideration which may influence the decision of whether to use anodic or cathodic cleaning or both is the rate at which the barrier layer material has a tendency to form a native oxide (M-O) and the tendency with which the native oxide is converted to metal hydride. If a barrier layer has a tendency to quickly form a metal oxide, anodic treatment followed by a cathodic treatment is suggested in order to form a species (e.g., M-H—O—) more suitable for electrochemical deposition of a metallized feature.

In cases where the adhesion between the barrier M-O and the seed layer metal is high, then anodic treatment of the barrier metal creating favorable species (M-O—) may be employed to improve adhesion, nucleation, and texture of the electrodeposited features.

After the barrier layer is placed in contact with the appropriate acid or alkaline solution, suitable power is applied to the barrier layer and to an electrode in contact with the solution. The particular current density, treatment time, and bath compositions are not believed to be critical and can be chosen to achieve the results described above. As an example, current densities can range on the order of about 10 mA/cm² or higher and suitable time periods for the electrolytic treatment may range from about 15 seconds to a minute. A suitable bath for electrolytic treatment described herein may incorporate about 1-20 weight % of an electrochemically inert neutral ionic salt, about 1-10 weight % of a strong acid, about 1-10 weight % of a strong base, or a combination of the above with/without small quantities of wetting agents. A suitable electrolytic cleaning bath need not contain any metal ions that are readily deposited onto the barrier layer. The bath should be moderately conductive to ensure treatment of the entire barrier layer surface without being subjected to large terminal effects. Preferably, the electrolytic treatment bath will contain constituents that are the same or similar to the bath used to subsequently plate metal onto the barrier layer, or at least to ensure that the constituents of the electrolytic treatment bath do not interfere with the subsequent deposition of the metallized feature onto the treated barrier layer.

In an alternative embodiment to this aspect of the present invention, the alkaline or acidic solution described above can be an alkaline or acidic plating bath that includes components useful to electrolytically deposit a metallized feature. In this embodiment, the cathodic treatment can be performed just below the deposition potential of the electroplating bath solution. Voltage control can be implemented to prevent the deposition of the metal ions until a sufficient period of time has elapsed to modify the surface of the barrier layer as described above. The anodic treatment can likewise be carried out in a potential range just below the oxygen evolution potential or just below the dissolution potential of the metal. In this way, the evolution of nascent oxygen or the dissolution of the metal may provide a clean, fresh surface/new species for electroplating another metal onto it. Carrying out the cathodic and/or anodic treatment using an electroplating bath has the inherent advantage that it is in situ and the wet transfer of the workpiece and drag out from the electrolytic treatment bath to the plating bath may be avoided. Additionally, by carrying out the treatment of the surface of the barrier layer in the same reactor where the metallized feature is to be deposited onto the treated barrier layer, exposure to oxygen and the resultant formation of the undesirable native oxides can be more readily controlled.

Electroplating Process and Solutions

Choice of appropriate electroplating bath compositions must take into consideration the electrical resistivity of the barrier metal. Failing to take into consideration the electrical resistivity of the barrier layer can result in non-uniform deposits of the metallized feature near the center of the wafer due to the non-uniform distribution of electroplating power across the wafer. The electroplating bath composition and the design of the chamber in which the electroplating of the metallized feature occurs should be chosen so that the potential drop across the wafer is as small as possible relative to the potential drop resulting from the electroplating bath composition and the chamber design. More uniform electroplating of metals onto the barrier layer can be achieved when the activation over potential required in surmounting the potential barrier for reaction and the concentration over potential can be increased. Other factors that can be modified to improve the uniformity of the deposited metallized feature across the surface of the wafer include use of multiple anodes to apply different currents on different zones of the wafer. Uniformity of the deposited metallized feature may also be improved by providing a current thief at the edge of the wafer to compensate for any terminal effect that might affect the uniformity of the deposited metal.

In accordance with a third aspect of the present invention, it is contemplated that an alloy composition of constant or varying composition described below for a seed layer can serve to supplement a barrier layer and serve as a bonding layer between a barrier layer that has not been acid treated or electrolytically treated as described above and a subsequently deposited metal feature. In this regard, it is not necessary to treat the barrier layer with acid or electrolytically, but rather directly deposit the described alloy onto a barrier layer that has not been acid or electrolytically treated as described herein, followed by depositing gap fill or bulk metallization onto the deposited alloy. In addition to the alloys described above, a bonding layer comprising a single metal may also serve to supplement and improve the adhesion between a barrier layer and subsequently deposited gap fill metallization. Examples of such metals that may be useful as a bonding layer include chromium, nickel, zinc, cobalt, aluminum, boron, magnesium, and cerium, or any other metal that adheres to the barrier layer material, as well as the material used for gap filling.

The composition of the alloy forming the metallized feature can be constant throughout or the composition of the alloy can vary from one surface of the feature to the opposing surface.

An example of an alloy of constant composition is given by the formula AxBy, where A represents a first metal species and B represents a second metal species, and wherein x and y represent the atomic percentage of the metal species A and the metal species B, respectively. Atomic percent (%) means the number of atoms of the element under discussion for every 100 atoms of the alloy composition x and y can be any value greater than 0 to less than 100%, so that the sum of x and y equal 100%. When the alloy is deposited as a seed layer, metal B can be a metal species that is also suitable to form a metallized feature on the alloy seed layer, such as copper. Without limitation, metal A can be chromium, nickel, zinc, cobalt, aluminum, boron, magnesium, and cerium or any other metal that is compatible with metal B and that provides an alloy that adheres to the metal used to form a metallized feature on the seed layer. The amounts of metal species A and metal species B can be chosen so as to provide optimum adhesion between the acid treated, electrolytically treated, or untreated barrier layer and the alloy seed layer. The amounts of metals A and B should also be chosen so that adequate deposition rates can be achieved as well as adequate coverage of the barrier layer.

The thickness of the alloy seed layer can be varied, taking into consideration a number of factors. For example, the alloy seed layer should be thick enough to provide adequate coverage of the barrier layer. In order to reduce processing time and material cost, alloy feature seed layer should be as thin as possible.

As noted above, the composition of the alloy seed layer can vary from the barrier layer interface to the interface at a metallized feature formed on the seed layer. In this embodiment, the composition of the alloy layer is high in the alloying metal species A near the barrier layer interface and high in the alloyed metal species B near the electroplated metallized feature formed on the seed layer. For example, metal species A in the alloy can be substantially 100 atomic % at the interface between the barrier layer and the alloy seed layer and substantially 0 atomic % at the interface between alloy feature and metallized feature deposited thereon. Conversely, the composition of metal species B can be substantially 0 atomic % at the barrier layer/alloy interface and substantially 100 atomic % at the alloy/metallized feature interface. The variation in the composition of the alloy seed layer can be altered, taking into consideration a number of factors such as the materials comprising the barrier layer and metallized feature deposited on the alloy seed layer. For example, metal species A might be chosen to be the same as the metal used to form the barrier layer and metal species B might be chosen to be the same as the metallized feature to be formed over the alloy seed layer.

The thickness of an alloy seed layer having varying composition as described above can vary. An appropriate thickness can be chosen, taking into consideration factors such as those described above with respect to an alloy seed layer of constant composition.

A bath composition suitable for depositing a copper-chromium alloy as the alloy seed layer may include the following constituents:

| Constituent | Concentration | |
|---|---|---|
| Cr SO₄ | 10-40 | g/l |
| Cu SO₄ | 5-20 | g/l |
| (NH₄)₂ SO₄ | 20-40 | g/l |
| NH₄ OH | 50-100 | ml/l |
| ED or EDTA | 0.1-1.0 | ml/l |

The bath may be formulated from a combination of available bath solutions with other adjuvants as desired.

In some instances, the bath solution may include additional agents such as brighteners, levelers, accelerators, and suppressors to facilitate formation of the alloyed seed layer.

While an electrolytically deposited alloyed seed layer feature is an embodiment of the present invention, the feature can alternately be deposited in accordance with the present invention using other deposition techniques such as electroless plating. Furthermore, the present invention is not limited to alkaline baths for depositing alloyed features, acidic baths, capable of depositing alloy seed layers are also within the scope of the present invention.

The electroplating system can be adjusted and/or programmed for the appropriate processing parameters to control the composition of the deposited alloy seed layer. Electroplating bath solution flow rate, pH, temperature, concentration of metals to be deposited, concentration of complexing agents for the metal species A and/or the second metal species B, current density, deposition potential and wave form of electroplating power applied, and rotation rate of workpiece can all affect the quality and composition of the deposited alloy seed layer. The adjustment and/or programming of these variables can take place either manually or using a programmable control system taking into consideration known criteria.

Without limitation, exemplary acidic bath processing parameters include a flow rate up to 5 gallons per minute for a plating bath solution having a temperature up to about 65° C., a pH up to about 4, and a concentration of metal ion species A and B in the range of about 2-16 grams per liter. Electroplating power having a current density in the range of about 20-50 mA/cm² is suitable. A pulse waveform having an on time of about 1-10 milliseconds, and an off time of about 1-10 milliseconds is suitable. Deposition rates in excess of 550 ångströms per minute are typical using the above noted acidic plating parameters.

Reference is made to U.S. Pat. No. 6,319,387 for its disclosure regarding the composition of useful copper alloys, baths for depositing such alloys, and processes for depositing such alloys. The disclosure of U.S. Pat. No. 6,319,387 is expressly incorporated herein by reference.

Following the deposition of an alloy seed layer, a second electroplating process can deposit gap fill metal or other features onto the alloy seed layer.

The deposition of metal alloy can be suitably carried out in commercially available apparatus, which are arranged and have controllers that are then modified to be programmed in accordance with desired parameters. An integrated processing tool that incorporates one or more chambers that are particularly suitable for implementing the foregoing electrochemical deposition, acid or electrolytic treatment and surface preparation processes is the LT210™ ECD system available from Kalispell, Mont., and as further described in International PCT Application No. WO 98/02911 (PCT/US97/12332), the disclosure of which is hereby expressly incorporated by reference. Other commercially available ECD systems such as the Equinox™ model tool, available from Semitool, Inc., are also suitable for use. Such tools are readily adapted to implement a wide range of processes used in the fabrication of microelectronic circuits and components. In addition to electroplating reactors, such tools frequently include other ancillary processing chambers, such as pre-wetting chambers, rinsing chambers, etc., that are used to perform other processes typically associated with electrochemical deposition. Semiconductor wafers, as well as other microelectronic workpieces, are processed in such tools in the reactors and are transferred between the processing stations, as well as between the processing stations and input/output stations, by a robotic transfer mechanism. The robotic transfer mechanism, the electroplating reactors, and the plating recipes used therein, as well as the components for the processing chambers are all under the control of one or more programmable processing units.

As an alternative to the reactors and tools described above for depositing metal alloy, a reactor employing an ion permeable barrier may be employed. Such reactors may also be used to deposit metals onto barrier layers treated as described herein. Below are described several different processes including processes that: 1) an anion permeable barrier, an inert anode, and low conductivity, low acid processing fluids to deposit a metal; 2) an anion permeable barrier, an inert anode, and low conductivity low acid processing fluids to deposit more than one metal; 3) an anion permeable barrier, a consumable anode, and low conductivity, low acid processing fluids to deposit more than one metal; 4) a cation permeable barrier, an inert anode, and low conductivity low acid processing fluids to deposit a metal; and 5) a cation permeable barrier, a consumable anode, and low conductivity low acid processing fluids to deposit a metal.

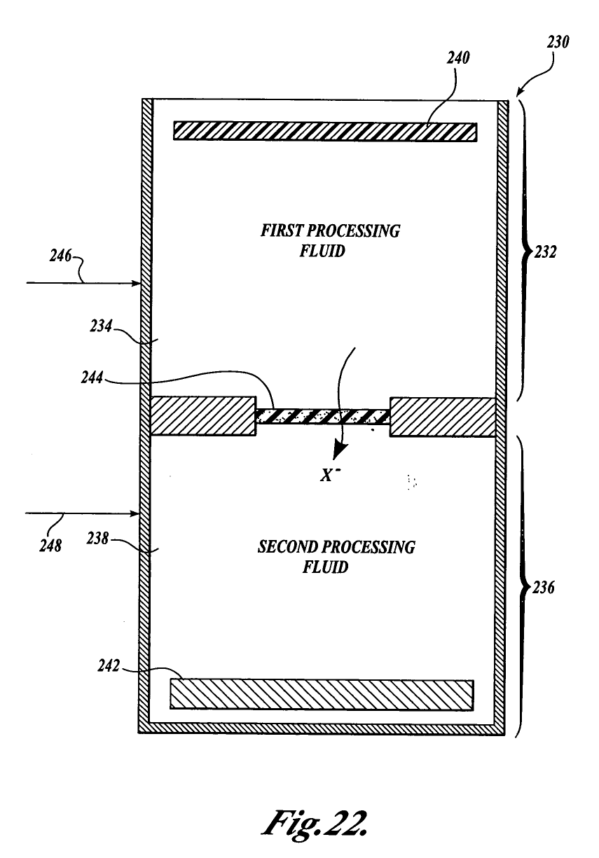

Deposition of metals onto the treated barrier layers described above or deposition of metal alloys onto untreated barrier layers described above can be carried out in an electrochemical reactor, e.g., an electroplating reactor, such as the one described below with reference to FIG. 22. Referring to FIG. 22, reactor 230 includes an upper processing unit 232 containing a first processing fluid 234 (e.g., a catholyte in an electroplating process) and a counter electrode unit 236 below the processing unit 232 that contains a second processing fluid 238 (e.g., anolyte in an electroplating process) which may be different in composition and/or properties from the first processing fluid 234. Processing unit 232 receives a working electrode 240 (e.g., a microfeature workpiece) and delivers the first processing fluid 234 to the working electrode 240. Counter electrode unit 236 includes a counter electrode 242 that is in contact with the second processing fluid 238. When metal is to be deposited onto working electrode 240, working electrode 240 is the cathode and counter electrode 242 is the anode. Accordingly, in plating applications, first processing fluid 234 is a catholyte and second processing fluid 238 is an anolyte. In general, the catholyte contains components in the form of ionic species, such as acid ions, hydroxyl ions, and metal ions, and a complexing agent capable of forming a complex with the metal ions. The catholyte may also include organic components such as accelerators, suppressors, and levelers that improve the results of the electroplating process. In addition, the catholyte may include a pH adjustment agent to affect the pH of the catholyte. The anolyte generally includes ionic species as well, such as acid ions, hydroxyl ions, and metal ions. The anolyte may also include a pH adjustment agent. Additional details regarding the various components in the catholyte and anolyte are provided below.

Reactor 230 also includes a nonporous anion permeable barrier 244 between the first processing fluid 234 and the second processing fluid 238. Nonporous anion permeable barrier 244 allows anions to pass through the barrier while inhibiting or substantially preventing non-anionic components, such as cations, from passing between the first processing fluid 234 and second processing fluid 238. By inhibiting or substantially preventing non-anionic components from passing between the first processing fluid 234 and second processing fluid 238, adverse effects on the deposited material resulting from the presence of unwanted non-anionic components, such as unwanted cations, in the first processing fluid 234 can be avoided. As such, nonporous anion permeable barrier 244 separates first processing fluid 234 and second processing fluid 238 such that first processing fluid 234 can have different chemical characteristics and properties than second processing fluid 238. For example, the chemical components of first processing fluid 234 and second processing fluid 238 can be different, the pH of the first processing fluid 234 and second processing fluid 238 can be different, and concentrations of components common to both first processing fluid 234 and second processing fluid 238 can be different.

Continuing to refer to FIG. 22, in the following description of an electroplating process, for consistency, working electrode 240 is referred to as the cathode and counter electrode 242 is referred to as the anode. Likewise, first processing fluid 234 is referred to as the catholyte and second processing fluid 238 is referred to as the anolyte. When reactor 230 is used to electrolytically process a microfeature workpiece to deposit metal ions thereon, an electric potential is applied between anode 242 and cathode 240. Copper ions in the catholyte are consumed by the deposition of copper ions onto the cathode. Meanwhile, the anode becomes positively charged and attracts negatively charged ions to its surface. For example, hydroxyl ions in the anolyte are attracted to the anode where they react to liberate oxygen and produce water. The foregoing results in a gradient of charge in the anolyte with unbalanced positively charged species in the anolyte solution and negatively charged species in the catholyte solution. This charge imbalance encourages the transfer of negatively charge anions through the anion permeable barrier 244 from catholyte 234 to the anolyte 238. An electrochemical reaction (e.g., losing or gaining electrons) occurs at cathode 240, resulting in metal ions being reduced (i.e., gaining electrons) to metal on surfaces of cathode 240.

Reactor 230 effectively maintains the concentration of metal ions in catholyte 234 constant during the electroplating process in the following manner. As metal ions are deposited onto the surface of cathode 240, additional metal ions are introduced to catholyte 234 from a source of metal ions 246, which is in fluid communication with upper processing unit 232. As explained below in more detail, these metal ions can be provided by delivering a metal salt solution to processing unit 232. Processing unit 232 can also be in fluid communication with sources of other components that need replenishment. In similar fashion, counter electrode unit 236 may be in fluid communication with sources of components that require replenishment. For example, counter electrode unit 236 can be in fluid communication with a source of pH adjustment agent 248. Likewise, both processing unit 232 and electrode unit 236 can include conduits or other structures (not shown) for removing portions of catholyte 234 from processing unit 232 or portions of anolyte 238 from counter electrode unit 236.

Anode 242 may be a consumable anode or an inert anode. Exemplary consumable anodes and inert anodes are described below in more detail.

U.S. Application Publication No. 2005/0087439 A1, from which the present application claims priority and which is incorporated herein in its entirety, describes other electrochemical deposition chambers that include a non-porous barrier separating processing fluids.

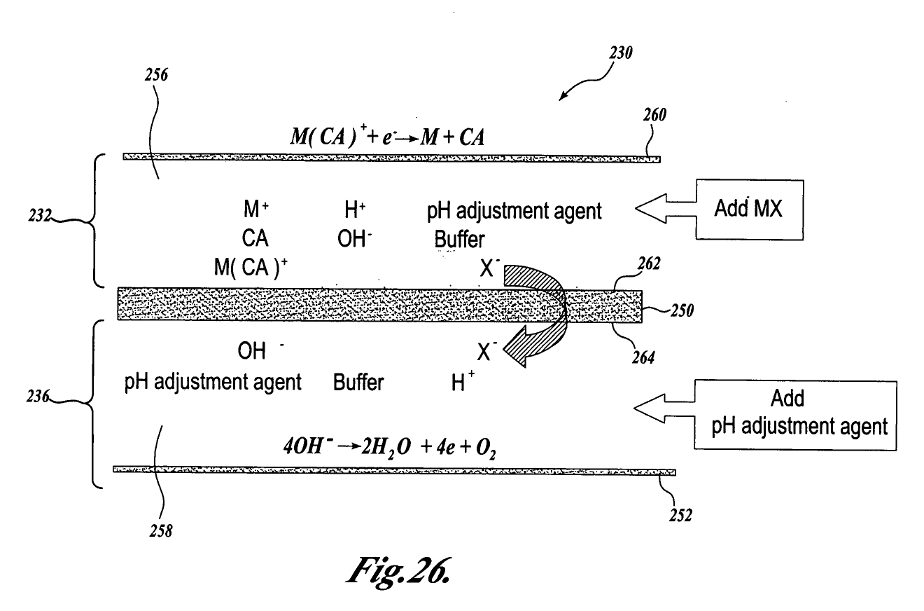

Referring to FIG. 26, the chemistry present in processing unit 232 and counter electrode unit 236 is described in more detail along with various chemical reactions that are believed to occur. It should be understood that by describing chemical reactions that are believed to occur within reactor 230, the processes described herein are not limited to processes wherein these reactions occur.

FIG. 26 schematically illustrates an example of the operation of reactor 230 using an anion permeable barrier 250 and an inert anode 252 in combination with a low conductivity/high pH first processing fluid 256 and a low conductivity/high pH second processing fluid 258 suitable for plating directly onto a barrier layer treated as described above. In the description that follows, high pH first processing fluid 256 in processing unit 232 is a catholyte containing a metal ion (M⁺), e.g., copper ions (Cu²⁺), a counter ion (X⁻) for the metal ion, e.g., sulfate ions (SO₄²⁻), a complexing agent CA described below, chelated with the metal ion M⁺, a pH buffer such as boric acid (H₃BO₃) that dissociates into hydrogen ions (H⁺) and H₂BO₃⁻, and a pH adjustment agent, such as tetramethylammonium hydroxide (TMAH) that dissociates into hydroxyl ion (OH⁻) and TMA⁺. The specific hydrogen ion concentration in catholyte 256 can be chosen taking into consideration factors such as complexing ability of the complexing agent, buffering capability of the buffer, metal ion concentration, volatile organics concentration, deposition potential of the complex at the particular pH, solubility of the catholyte constituents, stability of the catholyte, desired characteristics of the deposit, and diffusion coefficients of the metal ions.

For electroplating embodiments, high pH second processing fluid 258 in counter electrode unit 236 is an anolyte. Anolyte 258 can have a concentration of hydroxyl ions (OH⁻) that is approximately equal to the concentration of hydroxyl ions (OH⁻) in catholyte 256, although this is not required. By adjusting hydroxyl ion (OH⁻) concentration in anolyte 258 to be approximately equal to the concentration of hydroxyl ions (OH⁻) in catholyte 256, transfer of negatively charged hydroxyl ions from catholyte 256 to anolyte 258 through anion permeable membrane 250 during electroplating is inhibited. By inhibiting the transfer of negatively charged hydroxyl ions from catholyte 256 to anolyte 258, a more constant catholyte pH can be maintained. By maintaining pH of the catholyte relatively constant, the need to add pH adjustment agent to the catholyte is reduced or eliminated. This simplifies maintenance of the catholyte and helps to maintain the conductivity of the catholyte relatively stable through repeated plating cycles. In the description that follows with reference to FIG. 26, anolyte 258 includes a pH adjustment agent, such as TMAH, and a buffer, such as boric acid.

As mentioned above, during a plating cycle, an electric potential is applied between cathode 260 and anode 252. As metal ions (M⁺) are reduced and electroplated onto cathode 260, metal counter ions (X⁻) accumulate in the catholyte near a first surface 262 of anion permeable barrier 250. Additionally, depending on the pH of the anolyte at positively charged anode 252, hydroxyl ions (OH⁻) are converted to water (H₂O) and oxygen (O₂) and/or water is decomposed to hydrogen ions (H⁺) and oxygen. The resulting electrical charge gradient causes the negatively charged metal counter ions (X⁻) to move from first surface 262 of anion permeable barrier 250 to the second surface 264 of anion permeable barrier 250. The transfer of negatively charged metal counter ions (X⁻) from catholyte 256 to anolyte 258 during the plating cycle maintains the charge balance of reactor 230. To maintain the concentration of the negatively charged ions resulting from the dissociation of the pH buffer in catholyte 256 during electroplating, the concentration of the pH buffer in the anolyte may be set so it is significantly greater than the concentration of the pH buffer in the catholyte. This concentration differential inhibits the negatively charged ions resulting from the dissociation of the pH buffer in catholyte 256 from moving through anion permeable membrane 250 to anolyte 258 during electroplating. Continuing to refer to FIG. 26, during a plating cycle, as explained above, metal ions (M⁺) in catholyte 256 are reduced at cathode 260 and are deposited as metal (M). Metal ions that are consumed by the electroplating are replenished by the addition of a solution of metal salt (MX) to catholyte 256. During the plating cycle, metal counter ions (X⁻) which are introduced to catholyte 256 as a result of adding the metal salt (MX) transfer across anion permeable barrier 250 to anolyte 258. Portions of the anolyte can be removed from counter electrode unit in order to avoid the excessive build up of metal counter ions (X⁻) in anolyte 258. Non-anionic components in catholyte 256 (e.g., M⁺, H⁺, TMA⁺, H₃BO₃, and M(CA)⁺) generally do not pass through anion permeable membrane 250 and thus remain in catholyte 256. As described above, transfer of the hydroxyl (OH⁻) ion from the catholyte to the anolyte is minimized by maintaining pH of anolyte 258 at substantially the same level as pH of catholyte 256. Since hydroxyl ions are consumed at anode 252, a pH adjustment agent, such as TMAH, may be added to anolyte 258 as described above to maintain the pH of the anolyte at desired levels.

While the description relating to FIG. 26 refers to low conductivity, low acid processing fluids can also be high conductivity, high acid processing fluids. The low conductivity/high pH processing fluids described above are distinct from high conductivity, low pH processing fluids such as acidic electroplating baths described below in more detail. The concentration of H⁺ useful in high pH processing fluids may vary with those providing pHs above 7, preferably above 8 and most preferably above 9 being examples of useful high pH processing fluids.

As noted above, processes described herein are useful to electroplate metals other than copper, for example, gold, silver, platinum, nickel, tin, lead, ruthenium, rhodium, iridium, osmium, rhenium, and palladium. Metal ions useful in the catholyte can be provided from a solution of a metal salt. Exemplary metal salts include gluconates, cyanides, sulfamates, citrates, fluoroborates, pyrophosphates, sulfates, chlorides, sulfides, chlorites, sulfites, nitrates, nitrites, and methane sulfonates. Exemplary concentrations of metal salts in the catholyte used for plating applications range from about 0.03 to about 0.25 M.

The ability to electroplate metal ions can be affected by chelating the metal ion with a complexing agent. For example, in the context of the electroplating of copper, copper ions chelated with ethylene diamine complexing agent exhibit a higher deposition potential compared to copper ions that have not been chelated. Complexing agents useful for chelating and forming complexes with metal ions include chemical compounds having at least one part with the chemical structure COOR₁—COHR₂R₃ where R₁ is an organic group or hydrogen covalently bound to the carboxylate group (COO), R₂ is either hydrogen or an organic group, and R₃ is either hydrogen or an organic group. Specific examples of such type of complexing agents include citric acid and salts thereof, tartaric acid and salts thereof, diethyltartrate, diisoproyltartrate, and dimethyltartrate. Another type of useful complexing agent includes compounds that contain a nitrogen containing chelating group R—NR₂—R₁, wherein R is any alkyl group, aromatic group, or polymer chain and R₁ and R₂ are H, alkyl, or aryl organic groups. Specific examples of these types of complexing agents include ethylene diamine, ethylene diamine tetraacetic acid and its salts, cyclam, porphrin, bipyridyl, pyrolle, thiophene, and polyamines. In plating embodiments, suitable ratios between the concentration of metal ions and concentrations of complexing agents in the catholyte can range from 1:25 to 25:1; for example, 1:10 to 10:1 or 1:5 to 5:1.

The processing fluid making up the catholyte may include multiple species of a specific metal that is to be plated onto the cathode. For example, the catholyte may contain free metal ion species, hydrated metal ion species, metal chelated with organic agents, metal complexed with simpler agents, and multiple other metal complex species that provide a broad range of deposition potential at which acceptable deposits are obtained. With such a processing fluid, the free metal species could be plated first at a lower potential followed by a next metal complexed species at a next higher potential, and so on, until all the metal species are plated. The potential range across which the metal species of such a processing fluid could be plated is preferably continuous, so that some metal species are reduced and plated across a wide range of deposition potential. A wide potential range for the catholyte, high polarization, along with low conductivity of the catholyte, would be useful in forming metal features on barrier layers that exhibit acceptable uniformity and anisotropic metal conductivity.

Useful chelating agents include those described above and generally include molecules that have two or more moieties capable of complexing with a metal. Useful complexing agents of a simpler nature include only a single moiety capable of complexing with a metal. Ammonia (NH₃) is an example of such a complexing agent.

For alkaline processing fluids (high pH, low acid, low conductivity), useful pH adjustment agents include materials capable of adjusting the pH of the first processing fluid and the second processing fluid, for example, to above 7 to about 13 and, more specifically, above about 9.0. When ethylene diamine or citric acid is used as a complexing agent for copper ions, a pH of about 9.5 is useful. When ethylene diamine tetraacetic acid is used as a complexing agent for copper ions, a pH of about 12.5 is suitable. Examples of other suitable pH adjustment agents include alkaline agents such as potassium hydroxide, ammonium hydroxide, tetramethyl ammonium hydroxide, sodium hydroxide, and other alkaline metal hydroxides. A useful amount and concentration of pH adjustment agents will depend upon the level of pH adjustment desired and other factors, such as the volume of processing fluid and the other components in the processing fluid.

For acidic processing fluids (low pH, high conductivity, high acid), useful pH adjustment agents include materials capable of adjusting the pH of the first and second processing fluid to below 7. Useful complexing agents for acid processing fluids include pyrophosphate, citric acid, ethylene diamine, ethylene diamine tetraacetic acid, polyimines, polyimides, and polyamines.

Useful buffers for both alkaline and acidic processing fluids include materials that maintain the pH relatively constant, preferably at a level that facilitates complex formation and desirable complexed species. Boric acid was described above as an example of a suitable buffer. Other useful buffers include sodium acetate/acetic acid and phosphates. Exemplary concentrations of buffer range from about 0.001 to about 0.5 M in the catholyte for plating applications. Exemplary buffer concentrations for the anolyte range from about 0.001 M to about 1.0 M.

The catholyte can include other additives such as those that lower the resistivity of the fluid, e.g., ammonium sulfate; and those that increase the conformality of the deposit, e.g., ethylene glycol. For plating applications, exemplary concentrations of resistivity effecting agents in the catholyte range from about 0.01 to about 0.5M. For conformality affecting agents concentrations ranging from about 0 to 1.0M are exemplary. The catholyte may also contain other agents such as accelerators, suppressors, brighteners, levelers and the like.

In particular embodiments relating to copper metal deposition, catholyte electroplating compositions may comprise an aqueous mixture of copper and sulfuric acid wherein the ratio of the copper concentration to sulfuric acid concentration (all concentrations listed in g/L are grams per liter of solution) is equal to from about 0.3 to about 0.8 g/L. In other particular embodiments relating to copper metal deposition, the catholyte electroplating compositions may comprise a mixture of copper and sulfuric acid wherein the ratio of the copper concentration to the sulfuric acid concentration is equal to from about 0.4 to about 0.7 g/L. In yet other embodiments, the catholyte electroplating compositions may comprise a mixture of copper and sulfuric acid wherein the ratio of the copper concentration to the sulfuric acid concentration is equal to from about 0.5 to about 0.6 g/L.

In yet other embodiments relating to copper metal deposition, the catholyte electroplating compositions may comprise an aqueous mixture of copper and sulfuric acid wherein the copper concentration in the composition is within about 60% to about 90% of its solubility limit when the sulfuric acid concentration is from about 65 to about 150 g/L. In yet other embodiments relating to copper metal deposition, the catholyte electroplating compositions may comprise an aqueous mixture of copper and sulfuric acid wherein the copper concentration in the composition is within about 60% to about 90% of its solubility limit when the sulfuric acid concentration is from about 70 to about 120 g/L. In other particular embodiments relating to copper metal deposition, the catholyte compositions may comprise an aqueous mixture of copper at a concentration of from about 35 to about 60 g/L and sulfuric acid at a concentration of from about 65 to about 150 g/L. In other embodiments, the catholyte compositions may comprise an aqueous mixture of copper at a concentration of from about 45 to about 55 g/L and sulfuric acid at a concentration of from about 75 to about 120 g/L.

Other useful catholyte electroplating compositions for copper deposition may comprise an aqueous mixture of about 40 g/L copper and about 100 g/L sulfuric acid or about 50 g/L copper and about 80 g/L sulfuric acid. Other exemplary embodiments may comprise aqueous mixtures of about 60 g/L copper and about 65 g/L sulfuric acid or about 47 g/L copper and about 70 g/L sulfuric acid.

The catholyte electroplating compositions may contain other mineral acids in combination with or in place of sulfuric acid, such a fluoboric acid and the like, organic acids, such as methane sulfonic (MSA), amidosulfuric, aminoacetic, and combinations thereof, and the like, combinations of mineral acids and organic acids. The catholyte electroplating compositions may include further additives such as suppressors, accelerators, and levelers to assist in filling small features.

The catholyte electroplating compositions may also contain additives such as halide ions, for example, chloride, bromide, iodide, combinations thereof, and the like. In certain embodiments, chloride is added in combination with certain suppressing additives (e.g., polyethers) in an amount sufficient to interact and suppress deposition of copper at constant voltage, or to increase the over potential for a given applied current density. As is known to those persons of ordinary skill in the art, the concentrations of halides added are typically determined by the operating parameters chosen for the particular hardware. In certain embodiments of the catholyte compositions, the halogen concentration is from about 10 ppm to about 100 ppm. For example, about 50 ppm HCl may be added to a catholyte electroplating composition comprising about 50 g/L copper and about 80 g/L sulfuric acid. In another embodiment, about 20 ppm HCl is added to a catholyte electroplating composition comprising about 40 g/L copper and about 100 g/L sulfuric acid. Other suitable additives (as known to those persons of ordinary skill in the art) used to aid the suppressor in decreasing the deposition rate and/or to aid the accelerator in increasing the deposition rate may be added.

Suppressors generally increase cathodic polarization and adsorb on the substrate surface to inhibit or reduce copper deposition in the adsorbed areas. Suppressors added to the plating composition may include, e.g., two-element polyethylene glycol based suppressors, such as suppressors made of random/block copolymers of ethylene oxide and propylene oxide mixed in a wide range of ratios. For example, CUBATH ViaForm Suppressor (DF75), available from Enthone, Inc., of West Haven, Conn., or Shipley C-3100 suppressor, available from Shipley Company of Marlborough, Mass., may be used.

Embodiments of the catholyte electroplating compositions may include any suitable suppressor type and concentration. For example, CUBATH ViaForm DF75 suppressor at a concentration of from about 2 ml/L to about 30 ml/L, or about 2 to about 10 may be used. As further example, Shipley C-3100 suppressor at a concentration of from about 5 ml/L to about 25 ml/L, or about 10 to about 20 may be used. In one particular embodiment, about 2 ml/L of the CUBATH suppressor is used in a catholyte electroplating composition comprising about 50 g/L copper and about 80 g/L sulfuric acid. In another example, about 17.5 ml/L of Shipley C3100 suppressor, available from Shipley Company of Marlborough, Mass., is used in a catholyte electroplating composition comprising about 40 g/L copper and about 100 g/L sulfuric acid.

Accelerators reduce cathodic polarization and compete with suppressors for adsorption sites to accelerate copper growth in the adsorbed areas. The accelerators used in the catholyte plating composition may include, e.g., sulphur containing compounds, such as bis(soldium sulfopropyl)disulfide (SPS). Accelerators, with smaller molecular dimensions can diffuse faster than suppressors. For example, CUBATH ViaForm Accelerator (DF74) available from Enthone or Shipley B-3100 accelerator (available from Shipley), may be used. Embodiments of the catholyte electroplating compositions may include, for example, an accelerator such as the CUBATH ViaForm DF74. Such an accelerator may be used in any suitable concentration of from about 2 ml/L to about 30 ml/L, from about 2 to about 8 ml/L. For example, about 5 ml/L may be used in a catholyte electroplating composition comprising about 50 g/L copper and about 80 g/L sulfuric acid. In another embodiment, about 10 ml/L of Shipley B-3100 accelerator (available from Shipley) is used in a catholyte electroplating composition comprising about 40 g/L copper and about 100 g/L sulfuric acid.

Continued acceleration after filling the features may result in excess growth of copper over the features, creating surface protrusions. Thus, the addition of a leveler, such as CUBATH ViaForm Leveler DF79, available from Enthone, or Shipley U-3100 leveler (available from Shipley) may be added to the catholyte electroplating compositions. Other suitable levelers may be used to suppress the current at the protrusions to provide a leveled surface. Specific embodiments of the catholyte electroplating compositions include a leveler concentration of from about 0.5 ml/L to about 3 ml/L, or from about 1.0 to about 3.0 ml/L. For example, about 2.5 ml/L of the DF79 leveler may be used in a catholyte electroplating composition comprising about 50 g/L copper and about 80 g/L sulfuric acid. In another example, about 2 ml/L of Shipley U-3100 leveler (available from Shipley) may be used in a catholyte electroplating composition comprising about 40 g/L copper and about 100 g/L sulfuric acid.

The catholyte can also include other additives such as an additive or combination of additives that suppresses the growth of metal nuclei on itself while permitting metal deposition onto the treated barrier layers. Through the use of such additives or additive combinations, nucleation of deposit metal on barrier layers can be promoted over growth of the metal itself. By promoting the nucleation of the metal to be deposited on the barrier layer as opposed to the growth of metal nuclei itself, metal deposition that is conformal (i.e., uniformly lines that feature) and continuous at small dimensions, e.g., thicknesses will be promoted.

Useful anion permeable barriers include nonporous barriers, such as semi-permeable anion exchange membranes. A semi-permeable anion exchange membrane allows anions to pass but not non-anionic species, such as cations. The nonporous feature of the barrier inhibits fluid flow between first processing fluid 234 and second processing fluid 238 within reactor 230 in FIG. 22. Accordingly, an electric potential, i.e., a charge imbalance between the processing fluids and/or differences in the concentrations of substances in the processing fluids, can drive anions across an anion permeable barrier. In comparison to porous barriers, nonporous barriers are characterized by having little or no porosity or open space. Nonporous barriers generally do not permit fluid flow when the pressure differential across the barrier is less than about 6 psi. Because the nonporous barriers are substantially free of open area, fluid is inhibited from passing through the nonporous barrier. Water, however, may be transported through the nonporous barrier via osmosis and/or electro-osmosis. Osmosis can occur when the molar concentration in the first and second processing fluids are substantially different. Electro-osmosis occurs as water is carried through the nonporous barrier with current-carrying ions in the form of a hydration sphere. When the first and second processing fluids have similar molar concentrations and no electrical current is passed through the processing fluids, fluid flow between the first and second processing fluids via the nonporous barrier is substantially prevented.

A nonporous barrier can be hydrophilic so that bubbles in the processing fluids do not cause portions of the barrier to dry, which reduces conductivity through the barrier. Exemplary nonporous barriers include Ionac® membranes manufactured by Sybron Chemicals, Inc., and NeoSepta® manufactured by Asahi Kasei Company.

In addition to the nonporous barriers described above, anion permeable barrier can also be a porous barrier. Porous barriers include substantial amounts of open area or pores that permit fluid to pass through the porous barrier. Both ionic materials and nonionic materials are capable of passing through a porous barrier; however, passage of certain materials may be limited or restricted if the materials are of a size that allows the porous barrier to inhibit their passage. While useful porous barriers may limit the chemical transport (via diffusion and/or convection) of some materials in the first processing fluid and the second processing fluid, they allow migration of anionic species (enhanced passage of current) during application of electric fields associated with electrolytic processing. Examples of suitable porous barrier layers include porous glasses (e.g., glass frits made by sintering fine glass powder), porous ceramics (e.g., alumina and zirconia), silica aerogel, organic aerogels (e.g., resorcinol formaldehyde aerogel), and porous polymeric materials, such as expanded Teflon® (Gortex®). Suitable porous ceramics include grade P-6-C available from CoorsTek of Golden, Colo. An example of a porous barrier is a suitable porous plastic, such as Kynar™, a sintered polyethylene or polypropylene. Suitable materials can have a porosity (void faction) of about 25%-85% by volume with average pore sizes ranging from about 0.5 to about 20 micrometers. Such porous plastic materials are available from Poretex Corporation of Fairbum, Ga. These porous plastics may be made from three separate layers of material that include a thin, small pore size material sandwiched between two thicker, larger pore-sized sheets. An example of a product useful for the middle layer having a small pore size is CelGard™ 2400, made by CelGard Corporation, a division of Hoechst, of Charlotte, N.C. The outer layers of the sandwich construction can be a material such as ultra-fine grade sintered polyethylene sheet, available from Poretex Corporation. Porous barrier materials allow fluid flow across themselves in response to the application of pressures normally encountered in an electrochemical treatment process, e.g., pressures normally ranging from about 6 psi and below.

Inert anodes useful in electroplating processes described herein are also referred to as non-consumable anodes and/or dimensionally stable anodes and are of the type that when an electric potential is applied between a cathode and an anode in contact with an electrolyte solution, that there is no dissolution of the chemical species of the inert anode. Exemplary materials for inert anodes include platinum, ruthenium, ruthenium oxide, iridium, and other noble metals.

Consumable anodes useful in processes described herein are of the type that when an electric potential is applied between a cathode and an anode in contact with an electrolyte solution, dissolution of the chemical species making up the anode occurs. Exemplary materials for consumable anodes will include those materials that are to be deposited onto the microfeature workpiece, for example, copper, gold, tin, silver, lead, platinum, nickel, cobalt, zinc, and the like.

The temperature of the processing fluids can be chosen taking into consideration factors such as complexing ability of the complexing agent, buffering capability of the buffer, metal ion concentration, volatile organics concentration, deposition potential of the complexed metal at the particular pH, solubility of the processing fluid constituents, stability of the processing fluids, desired deposit characteristics, and diffusion coefficients of the metal ions. Generally, temperatures ranging from about 20° C.-35° C. are suitable, although temperatures above or below this range may be useful.

As described above in the context of an electroplating process using an ion permeable barrier, oxidation of hydroxyl ions or water at the anode produces oxygen capable of oxidizing components in the catholyte. When an anion permeable barrier is absent, oxidation of components in the electrolyte can also occur directly at the anode. Oxidation of components in the electrolyte is undesirable because it is believed that the oxidized components contribute to variability in the properties (e.g. resistivity) of the metal deposits. Through the use of an anion permeable barrier, as described above, transfer of oxygen generated at the anode from the anolyte to the catholyte is minimized and/or prevented, and, thus, such oxygen is not available to oxidize components that are present in the catholyte. As discussed above, one way to address the problem of oxygen, generated at the anode, oxidizing components in the processing fluid is to frequently replace the processing fluid. Because of the time and cost associated with frequently replacing the processing fluid, the processes described herein employing ion permeable barriers provide an attractive alternative by allowing the processing fluids to be used in repeated plating cycles without replacement. Use of the anion permeable barrier also isolates the anode from non-anionic components in the catholyte, e.g., complexing agent, that may otherwise be oxidized at the anode and adversely affect the ability of the catholyte to deposit features having resistivity properties that fall within acceptable ranges.

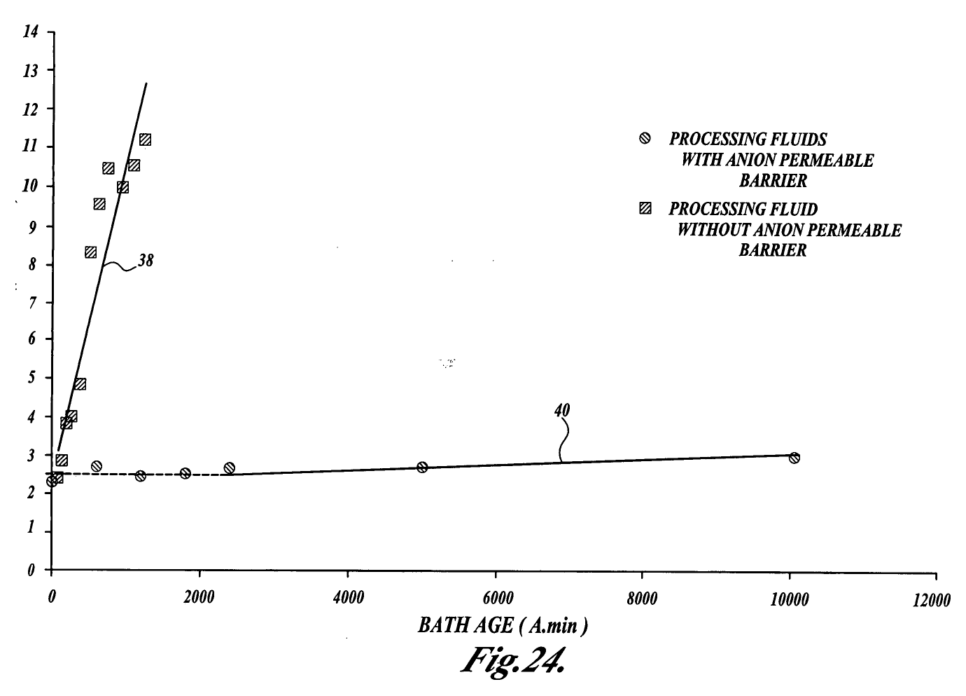

The resistivity of deposited metals as a function of the age of the processing fluid from which the deposit was formed is illustrated in FIG. 24. FIG. 24 illustrates how the use of processes described herein to deposit copper using ion permeable barriers significantly extends the useful operating life of a catholyte compared to conventional processes using similar chemistries without an anion permeable barrier. FIG. 24 illustrates test results evaluating the resistivity of several 20 nanometer copper seed layers deposited using the same chemistry in contact with the workpiece. One set of copper seed layers was formed using a process that did not employ an anion permeable barrier and a second set of copper seed layers was formed using a process that employed an anion permeable barrier in accordance with processes described herein. More specifically the resistivity of a deposit was measured using a 4-pt resistivity probe from Creative Design Engineering, Inc. that measures the sheet resistance of a substrate. The resistivity of the copper films was obtained as the product of sheet resistance and thickness of the thin film. Several wafers with the same seed layer resistance were obtained, and their sheet resistance was pre-measured (R_{PVD}). The wafers were then plated in a chamber with no membranes, inert anodes, and a 9.5 pH electrolyte. A fixed amp time was applied for each wafer (0.7 amp-min for a 300 mm wafer corresponding to 20 nm Cu thickness), and a theoretical amount of Cu film deposited on the seed layer was obtained at the same current density. The wafers were then rinsed and dried in a spin rinse dryer. The wafers were then measured in the 4-pt probe again. This provided a post sheet resistance measurement (Rₜₒₜₐₗ). With the two sheet resistance measurements, the sheet resistance of just the film deposited was obtained through the method of parallel subtraction using the formula shown below and the sheet of resistance of the electrodeposited seed layer was obtained.
R_{ECD Seed}=(R_{PVD}*Rₜₒₜₐₗ)/(R_{PVD}−Rₜₒₜₐₗ)

The resistivity of the deposited film was obtained by multiplying the thickness by the sheet resistance calculated above.
Resistivity of the electrodeposit=Thickness*R_{ECD Seed}=20 nm*R_{ECD Seed}

Several such wafers were plated periodically, as the bath ages in terms of amp-min (dummy wafers were plated to age the bath).

Similar sets of wafers were plated using an anionic membrane as described herein. The chamber utilized the same electrolyte as the catholyte used to plate the first set of wafers described above. The anolyte was a fluid consisting of buffer, pH adjustment agent, and of the same pH as the catholyte as described herein. The wafers were plated with the same amp time as before under substantially identical conditions.

Similar calculations were performed and the resistivity of the electrodeposit was obtained as a function of bath age.

The resistivity of seed layers deposited using a process without an anion permeable barrier (line 38), increases rapidly with the age of the bath, increasing more than three times in under 2000 amp minutes. By comparison, the resistivity of copper seed layers deposited using a process that employed an anion permeable membrane as described herein, illustrated by line 40, increases only gradually over time such that little increase is observed even after 10,000 amp minutes. These results illustrate how a process employing an ion permeable barrier as described herein substantially extends the useful life of processing fluids used to deposit metal features onto a microfeature workpiece.

Another advantage of employing an ion permeable barrier in the processes described herein is that the barrier prevents bubbles from the oxygen gas evolved at the anode from transferring to the catholyte. Bubbles in the catholyte are undesirable because they can cause voids or holes in the deposited features.

Another feature of processes described herein using an anion permeable barrier is that the pH adjustment agent, e.g., tetramethyl ammonium hydroxide (TMAOH), does not accumulate in the catholyte. As a result, excess cations of the pH adjustment agent need not be removed from the catholyte. This simplifies the maintenance of the catholyte.

In the foregoing descriptions, copper has been used as an example of a metal that can be used to form a metal feature directly onto a barrier layer treated as described above. However, it should be understood that the basic principles of the processes described herein and their use for the direct electroplating of a metal onto a barrier layer treated as described herein can be applied to other metals or alloys as well as deposition for other purposes. For example, gold is commonly used on for thin film head and III-V semiconductor applications. Gold ions can be electroplated using chloride or sulfite as the counter ion. As with copper, the chloride or sulfite counter ion would migrate across an anionic permeable barrier as described above in the context of copper. Potassium hydroxide could be used as the pH adjustment agent in a gold electroplating embodiment to counteract a drop in pH in the anolyte resulting from the oxidation of hydroxyl ions at the anode. As with the copper example described above, in the gold embodiment, gold chloride or gold sulfite, in the form of sodium gold sulfite or potassium gold sulfite could be added to the catholyte to replenish the gold deposited.

As mentioned previously, processes described above are useful for depositing more than one metal ion onto a microfeature workpiece surface. For example, processes described above are useful for depositing multi-component solders such as tin-silver solders. Other types of multi-component metal systems that could be deposited using processes described above include tin-copper, tin-silver-copper, lead-tin, nickel-iron, and tin-copper-antimony. Unlike certain copper features that are formed on the surfaces of microfeature workpieces, solder features tend to be used in packaging applications and are thus large compared to copper microfeatures. Because of their larger size, e.g., 10-200microns, solder features are more susceptible to the presence of bubbles in processing fluids that can become entrapped and affect the quality of the solder deposits. Thus to ability of processes described herein to isolate the catholyte from bubbles formed in the anolyte particularly advantageous in the deposition of solder features.

A tin-silver solder system is an example of a plating process that involves a metal with multiple valence states. Generally, metals with multiple valence states can be plated from most of their stable states. Since the charge required to deposit any metal is directly proportional to the electrons required for the reduction, metals in their valence states closest to their neutral states consume less energy for reduction to metal. Unfortunately, most metals in their state closest to their neutral states are inherently unstable, and therefore production-worthy plating can be difficult or unfeasible. Through the use of processes for plating metal ions described above, plating solutions that include metals in this inherently unstable state can be applied in an effective process to deposit the desired metal. As described below in more detail, through the use of the processes described above for depositing a metal, less oxidation of the inherently unstable metal species occurs, thus providing a more production-worthy process.

By way of illustration, most tin-silver plating solutions prefer Sn(I) as the species for tin plating. For such multi-component plating systems, control of tin and silver ions needs to be precise, and the use of silver or tin as an anode is not feasible. The use of such consumable anodes could cause stability issues resulting from plating/reacting with the anodes, and they also create issues relating to the ability to uniformly replenish metal. On the other hand, the use of inert anodes avoids the foregoing issues, but introduces a new issue associated with the production of oxygen through the oxidation of water or hydroxyl ions at the inert anode. Such oxygen not only may oxidize other components in the plating bath, it may also oxidize the desired Sn(II) species to the more stable Sn(IV) ion, which is more difficult to plate onto a workpiece.

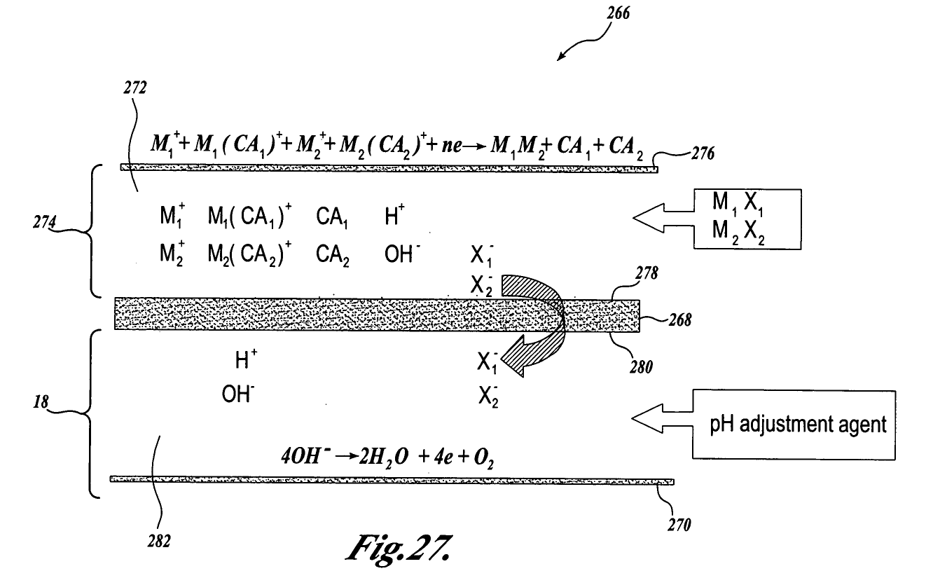

Referring to FIG. 27, a schematic illustration is provided for the operation of reactor 266 using an anion permeable barrier 268 and an inert anode 270 in combination with a first processing fluid 272 and a second processing fluid 282 suitable for depositing tin-silver solder. In the description that follows, processing fluid 272 in processing unit 274 is a catholyte containing metal ions M₁⁺ and M₂⁺, e.g., Sn²⁺ and Ag⁺ ions; counter ions X₁⁻ and X₂⁻ for the metal ions, e.g., methane sulfonate CH₃SO₃⁻; complexing agents CA₁ and CA₂, e.g., proprietary organic additives, chelated with the metal ions. As discussed above in the context of the electroplating of copper, the specific hydrogen ion concentration in catholyte 272 can be chosen taking into consideration conventional factors such as complexing ability of the complexing agent, buffering capability of the buffer, metal ion concentrations, volatile organics concentrations, alloy deposition potential of the complex at the particular pH, solubility of the catholyte constituents, stability of the catholyte, desired characteristics of the deposits, and diffusion, coefficients of the metal ions. Second processing fluid 282 is an anolyte containing metal counter ions X⁻₁ and X⁻₂ that have migrated from catholyte 272 to anolyte 282 through anion permeable barrier 268. Anolyte 282 also includes hydrogen ions H⁺ and hydroxyl (OH⁻) ions. Dissociated species from a pH adjustment agent may also be present in anolyte 282. The hydrogen ion concentration in anolyte 282 can be chosen taking into consideration the factors described above.

The discussions above regarding FIG. 26 and the concentration of H⁺ in the anolyte and catholyte, relative concentrations of the buffer in the anolyte and the catholyte, use of the pH adjustment agent, replenishment of the metal ions, cathodic reduction reactions, and anodic oxidation reactions in the context of the electroplating of copper are equally applicable to a tin-silver system. The particular operating conditions that are most desirable are related to the specific chemistry being used.

As with the metal plating process of FIG. 26, an electric potential applied between cathode 276 and anode 270 results in metal ions M₁⁺ and M₂⁺ being reduced at cathode 276 and deposited thereon. The metal counter ions X₁⁻ and X₂⁻, e.g., methane sulfonate (MSA) (CH₃SO₃⁻), accumulate in the catholyte near a first surface 278 of anion permeable barrier 268. As with the copper system, at positively charged anode 270, hydroxyl ions are converted to water and oxygen and/or water is decomposed to hydrogen ions and oxygen depending on the pH of the solution. The resulting electrical charge gradient causes negatively charged counter ions X₁⁻ and X₂⁻ to move from first surface 278 of anion permeable barrier 268 to the second surface 280 of anion permeable barrier 268. The transfer of negatively charged counter ions X₁⁻ and X₂⁻ from catholyte 272 to anolyte 282 during the plating cycle maintains the charge balance of reactor 266. Metal ions M₁⁺ and M₂⁺ that are deposited onto cathode 276 can be replenished by the addition of a solution of metal salts M₁X₁ and M₂X₂ to the catholyte. During the plating cycle, metal counter ions that are introduced to catholyte 272 as a result of the addition of the metal salts transfer across anion permeable barrier 268 to anolyte 282. As with the copper process, portions of anolyte 282 can be removed from counter electrode unit 284 to avoid the buildup of metal counter ions in the anolyte. As noted above, if necessary, pH adjustment agent can be added to anolyte 282 to control pH within desired ranges.

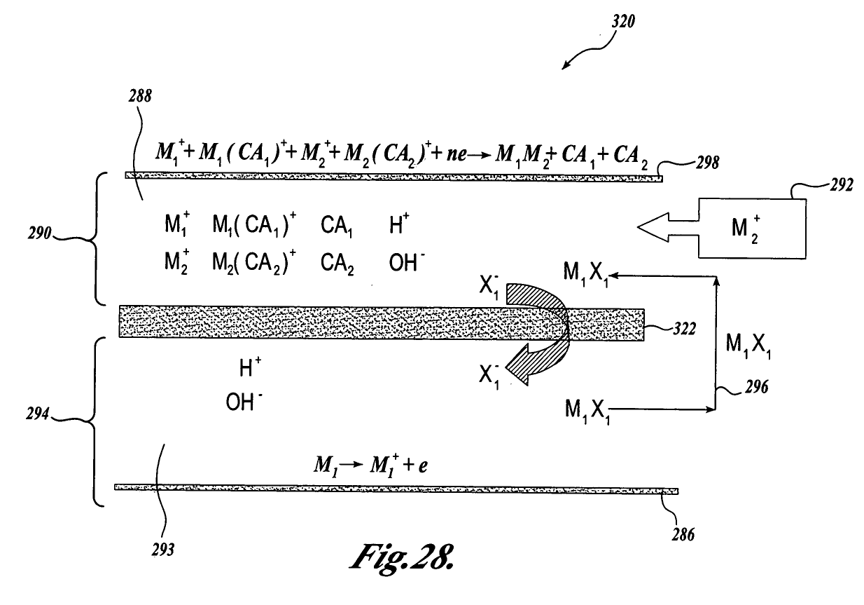

Referring to FIG. 28, electroplating two metals, e.g., tin and silver, can be achieved using a consumable anode 286. Referring to FIG. 28, the catholyte 288 in processing unit 290 is similar to the catholyte described with reference to FIG. 27. In the process depicted in FIG. 28, metal ion M₂⁺ is introduced into processing unit 290 from source 292. Metal ion M₁⁺ is supplied to counter electrode unit 294 through oxidation of metal making up consumable anode 286. Metal ion M₁⁺ combines with counter ion X₁⁻ in counter electrode unit 294 to form the metal salt M₁X₁ which is then available for delivery via line 296 to processing unit 290. Metal salt M₁X₁ delivered to processing unit 290 dissociates therein to provide a source of metal ion M₁⁺ that can be reduced at cathode 298 and deposited in combination with metal ion M₂⁺ as described above with reference to FIG. 27. In accordance with this embodiment, complexing agents CA₁ and CA₂ are present in catholyte 288 where they can complex with metal ions M₁⁺ and M₂⁺. Suitable pH adjustment agents and pH buffers may be present and/or added to the catholyte and anolyte. The charge balance within reactor 320 is maintained through the transfer of negatively charged counter ion X₁⁻ from processing unit 290 across anion permeable membrane 322 into counter electrode unit 294.

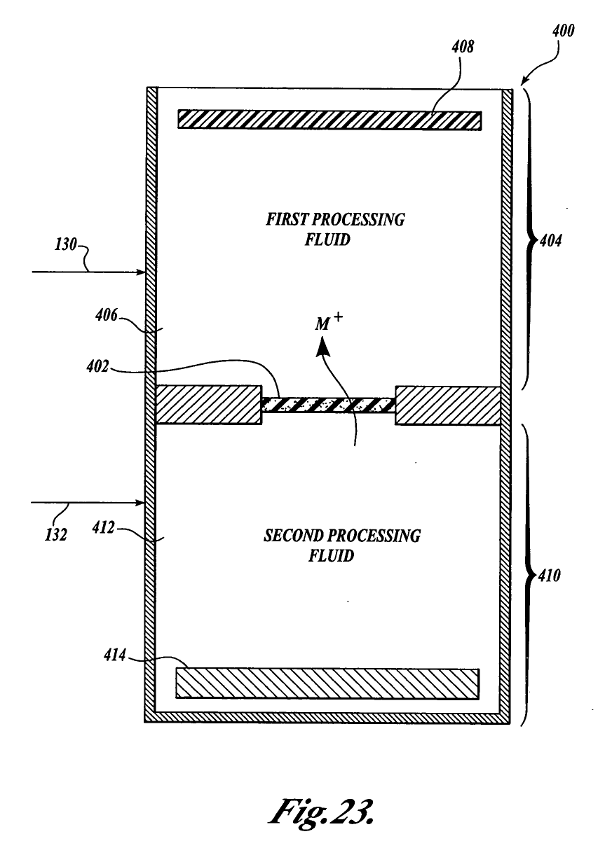

Depositing metals onto treated barrier layers described herein is not limited to processes that employ anion permeable barriers. Metals can be deposited onto treated barrier layers using processes that employ a cation permeable barrier. Referring to FIG. 23, which is similar to FIG. 22 but differs in that electrochemical deposition chamber 400 includes a cation permeable barrier 402 as the ion permeable barrier, as opposed to the anion permeable barrier of FIG. 22. Chamber 400 includes processing unit 404 that provides a first processing fluid 406 (e.g., a catholyte) to a workpiece 408 (i.e., working electrode) and an electrode unit 410 that provides a second processing fluid 412 (e.g., anolyte) different than the first processing fluid 406, and an electrode 414 (i.e., counter electrode). The catholyte 406 typically contains components in the form of ionic species such as acid ions and metal ions, as described above. The catholyte may also include other components, such as pH adjustment agents, buffers, chelating agents, accelerators, suppressors, and levelers that may improve the results of the electroplating process as described above. The anolyte 412 typically includes ionic components such as acid ions and metal ions and other additives such as pH adjustment agents and buffers. Cation permeable barrier 402 separates first processing fluid 406 from the second processing fluid 412. Cation permeable barrier 402 allows cations (e.g., H⁺ and Cu²⁺) to pass through the barrier, but inhibits non-cationic species such as organic components (e.g., accelerators, suppressors, and levelers) and anionic components from passing between the first and second processing fluids. As such, cation permeable barrier 402 separates components of the first processing fluid 406 and the second processing fluid 412 from each other such that the first processing fluid can have different chemical characteristics than the second processing fluid.

The cation permeable barrier provides several advantages by substantially preventing certain anionic species and organic components from migrating between the catholyte and the anolyte. For example, organic components from the catholyte are unable to flow past the anode and decompose into products that may interfere with the plating process. Second, because organic components do not pass from the catholyte to the anolyte, they are consumed at a slower rate so that it is less expensive and easier to control the concentration of organic components in the catholyte. Third, the risk of passivation by reaction of the anode with organic components is reduced or eliminated. In addition, the presence of the cation permeable barrier reduces the chances that metal flakes or small particles that flake off of the anode due to passivation when a consumable anode is used in combination with a high pH, low conductivity, low acid anolyte reach the workpiece where the flakes or particles may adversely impact the deposited metal.

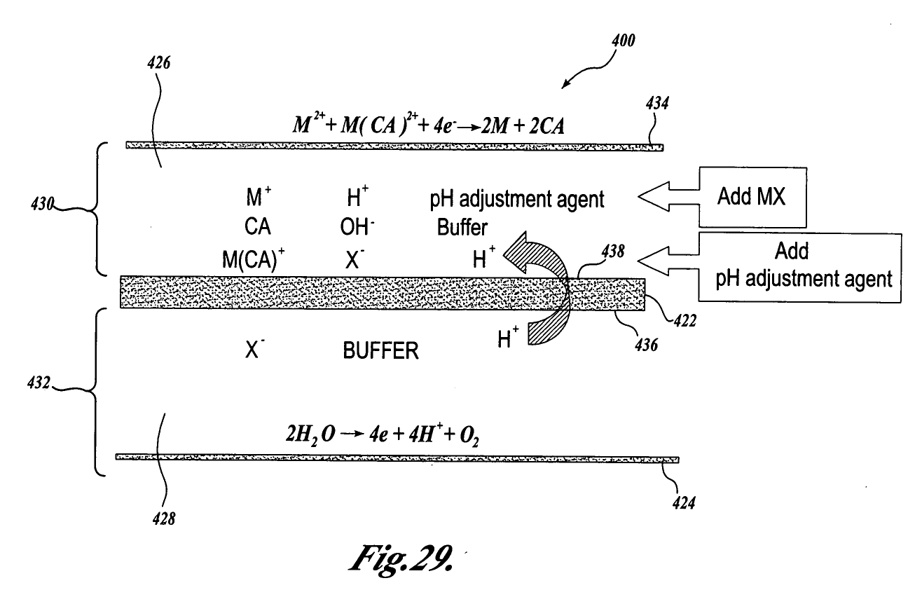

Referring to FIG. 23, the chemistry present in processing unit 404 in FIG. 23 and counter electrode unit 410 of FIG. 23 are described below with reference to FIG. 29. It should be understood that by describing chemical reactions that are believed to occur within reactor 400, the processes described herein are not limited to processes wherein these reactions occur.

FIG. 29 schematically illustrates an example of the operation of reactor 400 using a cation permeable barrier 422 and an inert anode 424 in combination with a low conductivity/high pH catholyte 426 and a low conductivity/high pH anolyte 428 suitable for plating metals directly onto a barrier layer treated as described above. In the description that follows, catholyte 426 in processing unit 430 contains a metal ion (M⁺), e.g., copper ion (Cu²⁺), a counter ion (X⁻) for the metal ion, e.g., sulfate ion (SO₄²⁻), a complexing agent CA, as described above, chelated with the metal ions, a pH buffer such as boric acid (H₃BO₃) that dissociates into hydrogen ions (H₊) and H₂BO₃⁻ and a pH adjustment agent, such as tetramethylammonium hydroxide (TMAH) that dissociates into hydroxyl ion (OH⁻) and TMA⁺. The specific hydrogen ion concentration and pH of catholyte 426 can be chosen taking into consideration conventional factors such as complexing ability of the complexing agent, buffering capability of the buffer, metal ion concentrations, volatile organics concentrations, deposition potential of the complex at the particular pH, solubility of the catholyte constituents, stability of the catholyte, desired characteristics of the deposits, and diffusion coefficients of the metal ions. Exemplary compositions for the catholyte have been described above with reference to the embodiment employing an anionic permeable barrier. Low conductivity, low acid anolyte 428 in electrode unit 432 includes an aqueous solution of an acid, e.g., sulfuric acid that dissociates into hydrogen ion (H⁺) and sulfate ions (SO₄²⁻). Anolyte 428 may also include a buffer. The hydrogen in concentration of anolyte 428 is preferably greater than the hydrogen in concentration of catholyte 426. This differential encourages the movement of hydrogen ions from the anolyte 428 to the catholyte 426. In order to account for this increasing hydrogen ion concentration in catholyte 426, pH adjustment agents can be added to catholyte 426. Hydrogen ions from anolyte 428 that migrate across cation permeable barrier 422 to catholyte 426 are replenished in anolyte 428 by the oxidation of water at anode 424, which produces hydrogen ions.

During a plating cycle, an electric potential is applied between cathode 434 and inert anode 424. As metal ions are reduced and electroplated onto cathode 434, hydrogen ions (H⁺) accumulate in the anolyte 428 near a first surface 436 of cation permeable barrier 422. The resulting electrical charge gradient and concentration gradient causes the positively charged hydrogen ions to move from first surface 436 of cation permeable barrier 422 to the second surface 438 of cation permeable barrier 422 that is in contact with catholyte 426. The transfer of positively charged hydrogen ions from anolyte 428 to catholyte 426 during the plating cycle maintains the charge balance of reactor 400. The electrical charge gradient created by applying an electric potential between cathode 434 and anode 424 also hinders the migration of cations, e.g., metal ions M⁺ and cations of pH adjustment agent from transferring from catholyte 426 to anolyte 428 through cation permeable barrier 422. In order to avoid the build up of counter ions (X⁻) of the metal ions and cations of the pH adjustment agent in the catholyte, these ionic and cationic species can be removed from the catholyte 426.

Continuing to refer to FIG. 29, during a plating cycle, as explained above, metal ions in catholyte 426 are reduced at cathode 434 and are deposited as metal. Metal ions that are consumed by the electroplating are replenished by the addition of a solution of metal salt MX to catholyte 426.

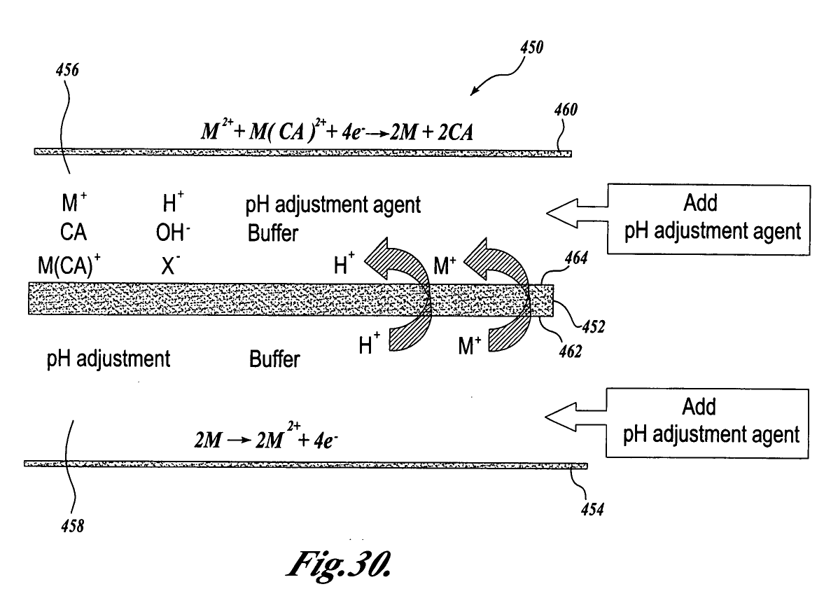

Metals may also be deposited using a cation permeable barrier and a consumable anode. Referring to FIG. 30, reactor 450, that includes a cation permeable barrier 452, a consumable anode 454, a low conductivity/high pH catholyte 456 and a low conductivity/high pH anolyte 458, is illustrated. For the embodiment of FIG. 30, catholyte 456 can have a composition that is similar to the composition of catholyte 426 described with reference to FIG. 29. Anolyte 458 includes hydrogen ions (H⁺) and metal ions (M⁺) from dissolution of consumable anode 454. Anolyte 458 can also include a buffer and dissociation products of pH adjustment agent. It is preferred that positively charged metal ions (M⁺) transfer across cation permeable barrier 454 as opposed to positively charged hydrogen ions (H⁺). Accordingly, it is preferred that anolyte 458 be a low acid/high pH anolyte so that there is an absence of a hydrogen ion concentration gradient between catholyte 456 and anolyte 458 that would promote the migration of the hydrogen ions from anolyte 458 to catholyte 456. Furthermore, by inhibiting the transfer of positively charged hydrogen ions from anolyte 458 to catholyte 456, a more constant catholyte pH can be maintained and the need to add a pH adjusting agent to the catholyte can be reduced. As noted above, this simplifies maintenance of the catholyte and helps to maintain the conductivity of the catholyte relatively stable during repeated plating cycles.

Continuing to refer to FIG. 30, during a plating cycle, an electric potential is applied between cathode 460 and anode 454. Metal is oxidized at anode 454 and metal ions (M⁺) accumulate in the anolyte near a first surface 462 of cation permeable barrier 452. The resulting electrical charge gradient causes the positively charged metal cations (M⁺) to move from the first surface 462 of cation permeable barrier 452 to the second surface 464 of cation permeable barrier 452. The transfer of positively charged metal ions from anolyte 458 to catholyte 456 during the plating cycle maintains the charge balance of reactor 450. During the plating cycle, metal ions (M⁺) in catholyte 456 are reduced at cathode 460 and deposited as metal.

Useful cation permeable barriers are generally selective to positively charged ions, e.g., hydrogen ions and metal ions; therefore, hydrogen ions and metal ions may migrate through the useful cation permeable barriers.

Examples of useful cation permeable barriers include commercially available cation permeable membranes. For example, Tokuyama Corporation manufactures and supplies various hydrocarbon membranes for electrodialysis and related applications under the trade name Neosepta™. Perfluorinated cation membranes are generally available from DuPont Co. as Nafion™ membranes N-117, N-450, or from Asahi Glass company (Japan) under the trade name Flemion™ as Fx-50, F738, and F893 model membranes. Asahi Glass Company also produces a wide range of polystyrene based ion-exchange membranes under the trade name Selemion™, which can be very effective for concentration/desalination of electrolytes and organic removal (cation membranes CMV, CMD, and CMT and anion membranes AMV, AMT, and AMD). There are also companies that manufacture similar ion-exchange membranes (Solvay (France), Sybron Chemical Inc. (USA), Ionics (USA), and FuMA-Tech (Germany), etc.). Bipolar membranes, such as models AQ-BA-06 and AQ-BA-04, for example, are commercially available from Aqualitics (USA) and Asahi Glass Company may also be useful.

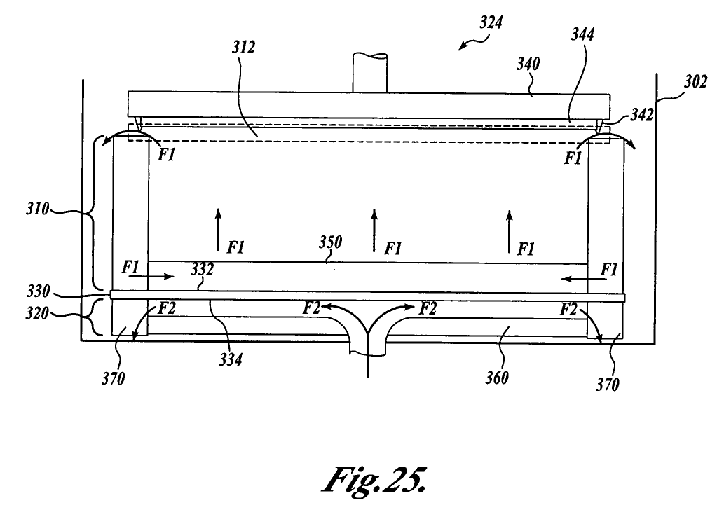

Referring to FIG. 25, a more detailed schematic illustration of one design of a reactor 324 for directly electroplating metal onto barrier layers or otherwise depositing materials onto workpieces using an ion permeable barrier is illustrated. Reactor 324 includes a vessel 302, a processing chamber 310 configured to direct a flow of first processing fluid to a processing zone 312, and an anode chamber 320 configured to contain a second processing fluid separate from the first processing fluid. An ion permeable barrier 330 separates the first processing fluid in the processing unit 310 from the second processing fluid in the anode chamber 320. Reactor 320 further includes a workpiece holder 340 having a plurality of electrical contacts 342 for applying an electric potential to a workpiece 344 mounted to workpiece holder 340. Workpiece holder 340 can be a movable head configured to position workpiece 344 in processing zone 312 of processing unit 310, and workpiece holder 340 can be configured to rotate workpiece 344 in processing zone 312. Suitable workpiece holders are described in U.S. Pat. Nos. 6,080,291; 6,527,925; 6,773,560, and U.S. patent application Ser. No. 10/497,460; all of which are incorporated herein by reference.

Reactor 324 further includes a support member 350 in the processing chamber 310 and a counter electrode 360 in the anode chamber 320. Support member 350 spaces the ion permeable barrier 330 apart from workpiece processing zone 312 by a controlled distance. This feature provides better control of the electric field at processing zone 312 because the distance between the ion permeable barrier 330 and workpiece processing zone 312 affects the field strength at processing zone 312. Support member 350 generally contacts first surface 332 of ion permeable barrier 330 such that the distance between first surface 332 and processing zone 312 is substantially the same across processing chamber 310. Another feature of support member 350 is that it also shapes ion permeable barrier 330 so that bubbles do not collect along a second side 334 of ion permeable barrier 330.

Support member 350 is configured to direct flow F₁ of a first processing fluid laterally across first surface 332 of ion permeable barrier 330 and vertically to processing zone 312. Support member 350 accordingly controls the flow F₁ of the first processing fluid in processing chamber 310 to provide the desired mass transfer characteristics in processing zone 312. Support member 350 also shapes the electric field in processing chamber 310.

Counter electrode 360 is spaced apart from second surface 334 of ion permeable barrier 330 such that a flow F₂ of the second processing fluid moves regularly outward across second surface 334 of ion permeable barrier 330 at a relatively high velocity. Flow F₂ of the second processing fluid sweeps oxygen bubbles and/or particles from the ion permeable barrier 330. Reactor 324 further includes flow restrictor 370 around counter electrode 360. Flow restrictor 370 is a porous material that creates a back pressure in anode chamber 320 to provide a uniform flow between counter electrode 360 and second surface 334 of the ion permeable barrier 330. As a result, the electric field can be consistently maintained because flow restrictor 370 mitigates velocity gradients in the second processing fluid where bubbles and/or particles can collect. The configuration of counter electrode 360 and flow restrictor 370 also maintains a pressure in the anode chamber 320 during plating that presses the ion permeable barrier 330 against support member 350 to impart the desired contour to ion permeable barrier 330.

Reactor 324 operates by positioning workpiece 344 in processing zone 312, directing flow F₁ of the first processing fluid through processing chamber 310, and directing the flow F₂ of the second processing fluid through anode chamber 320. As the first and second processing fluids flow through reactor 324, an electric potential is applied to workpiece 344 via electrical contacts 342 and counter electrode 360 to establish an electric field in processing chamber 310 and anode chamber 320.

Another useful reactor for depositing metals using processes described herein is described in U.S. Patent Application No. 2005/0087439, which is expressly incorporated herein by reference.

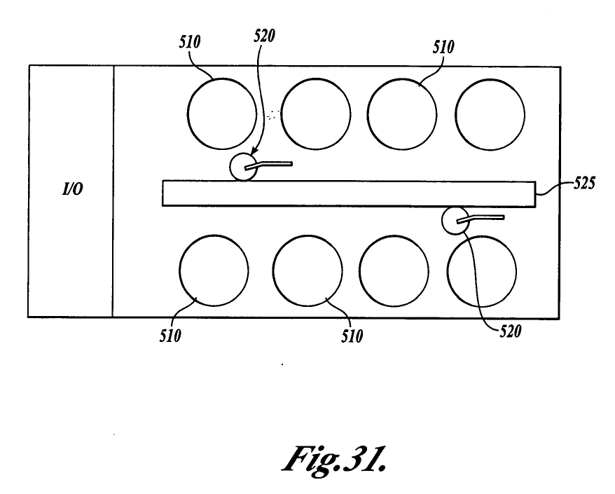

One or more of the reactors for electrolytically treating a microfeature workpiece or systems including such reactors may be integrated into a processing tool that is capable of executing a plurality of methods on a workpiece. One such processing tool is an electroplating apparatus available from Semitool, Inc., of Kalispell, Mo. Referring to FIG. 31, such a processing tool may include a plurality of processing stations 510, one or more of which may be designed to carry out an electrolytic processing of a microfeature workpiece as described above. Other suitable processing stations include one or more rinsing/drying stations and other stations for carrying out wet chemical processing. The tool also includes a robotic member 520 that is carried on a central track 525 for delivering workpieces from an input/output location to the various processing stations.

### EXAMPLE 1

Acid Treatment of Barrier Layer

Acid treatment of a tantalum barrier was performed using 2% by weight aqueous solution of hydrofluoric acid. A 200 mm blanket wafer deposited with 25 nanometers of PVD tantalum barrier was used. This rotating wafer was subjected to a water spray treatment for 15 seconds followed by an acid spray treatment for 15 seconds. Then the rotating wafer was cleaned by spraying de-ionized water for another 15 seconds to remove the excess acid from its surface. For an additional 5 seconds, the wafer was rotated to sling off large water droplets. The wafer was then wet-transferred to a plating chamber. In the plating chamber, the wafer was plated with copper up to a thickness of ˜80 nanometers. After plating, the wafer was cleaned in situ with de-ionized water and the wafer was transferred to a SRD (Spin, Rinse, and Dry) chamber. In this SRD chamber, the spinning wafer was once again cleaned with de-ionized water thoroughly to remove any plating chemistry left on its surface. After rinsing, the wafer was dried by spinning it in the chamber for several seconds at various rates. After drying, the wafer can be transferred to an anneal/thermal station where it may be further processed. At this stage before the thermal processing, the wafer needs to be intact, with no adhesion losses. FIG. 19 shows a close-up of the edge of the processed wafer before thermal treatment. No adhesion loss is evident. FIG. 17 shows a wafer processed as described above without an acid pre-treatment. Poor adhesion is evidenced at the edge of the wafer of FIG. 17. After the plating of thin seed layer, the wafer may be further processed with an acid-copper gap-fill type chemistry in another electroplating chamber. After rinsing and drying the wafer, annealing of the wafer can be performed in an anneal chamber, before CMP processing to remove excess unwanted metals to form electrically isolated structures.

### EXAMPLE 2

Electrolytic Treatment of Barrier Layer

Electrolytic treatment of a tantalum barrier was performed using 2% by weight of potassium hydroxide aqueous solution. A 200 mm blanket wafer with 25 nanometers of PVD tantalum barrier was treated. This rotating wafer was used as a cathode and subjected to a current of 1 A (˜3 mA/cm²) for one minute while an inert platinum electrode was the anode. The wafer was then wet-transferred to a SRD chamber where the spinning wafer was rinsed with de-ionized water and then once again wet transferred to a plating chamber. In the plating chamber, the wafer was plated with copper up to a thickness of about 80 nanometers. After plating, the wafer was cleaned in situ with de-ionized water and the wafer was transferred to a SRD chamber. In this SRD chamber, the spinning wafer was once again cleaned with de-ionized water thoroughly to remove any plating chemistry left on its surface. After rinsing, the wafer was dried by spinning it in the chamber for several seconds at various rates. After drying, the wafer can be transferred to an anneal/thermal station where it could be further processed. At this stage before the thermal processing, the wafer needs to be intact, with no adhesion losses.

FIG. 21 shows a close-up of the edge of the wafer before thermal treatment. The wafer in FIG. 21 evidences no adhesion loss compared to the water in FIG. 12 (adhesion loss at the edge) processed similarly without the electrolytic pre-treatment. After the plating of a thin seed layer, the wafer may be further processed with an acid-copper gap-fill type chemistry in another electroplating chamber. After rinsing and drying the wafer, annealing of the wafer can be performed in an anneal chamber, before CMP processing to remove excess unwanted metals to form electrically isolated structures.

While preferred embodiments have been illustrated and described, it will be appreciated that various changes can be made therein without departing from the spirit and scope of the subject matter described herein.

The embodiments of the invention in which an exclusive property or privilege is claimed are defined as follows:

1. A method for forming a metallized feature on a surface of a microelectronic workpiece, comprising steps for:
providing a microelectronic workpiece including a barrier layer;
contacting a surface of the barrier layer with an acid solution in the absence of electroplating power to form an acid-treated surface of the barrier layer, the acid content of the acid solution being less than about 5 weight %;
contacting a portion of the acid treated surface with a first processing fluid, the first processing fluid comprising first processing fluid species including a cation, an anion, and a complexing agent;
contacting a counter electrode with a second processing fluid;
producing an electrochemical reaction at the counter electrode; and
substantially preventing movement of ionic species between the first processing fluid and the second processing fluid species.

2. The method of claim 1, wherein the acid solution is an inorganic acid solution.

3. The method of claim 1, wherein the step of substantially preventing movement of ionic species between the first processing fluid and the second processing fluid comprises providing an ion permeable barrier between the first processing fluid and the second processing fluid.

4. The method of claim 3, wherein the ion permeable barrier is an anion permeable barrier.

5. The method of claim 4, wherein the cation of the first processing fluid is a metal cation, and further comprising the step of electrolytically depositing the metal cation onto the acid treated surface.

6. The method of claim 5, wherein the first processing fluid further includes a counter anion of the metal cation and the process further comprises the step of passing the counter anion from the first processing fluid to the second processing fluid through the anion permeable barrier.

7. The method of claim 1, wherein the counter electrode is an inert anode.

8. The method of claim 1, wherein the counter electrode is a consumable anode.

9. The method of claim 1, wherein the first processing fluid has a pH greater than 7.0.

10. The method of claim 1, further comprising the step of adding a metal cation to the first processing fluid.

11. The method of claim 1, wherein the first processing fluid species further include a pH adjustment agent and a buffer.

12. The method of claim 11, wherein the second processing fluid comprises a pH adjustment agent and a buffer.

13. The method of claim 12, wherein buffer concentration in the first processing fluid is equal to or less than buffer concentration in the second processing fluid.

14. The method of claim 1, wherein the complexing agent is selected from the group consisting of ethylene diamine, ethylene diamine tetraacetic acid and its salts, cyclam, porphrin, bipyridyl, pyrolle, thiophene, and polyamines.

15. The method of claim 1, wherein the complexing agent is selected from compounds that contain a nitrogen-containing chelating group R—NR₂—R₁, where R is any alkyl group, aromatic group, or polymer chain, and R₁ and R₂ are H, alkyl or aryl organic groups.

16. The method claim 1, wherein the complexing agent includes chemical compounds having at least one part with the chemical structure COOR₁—COHR₂R₃ where R₁ is an organic group or hydrogen covalently bound to the carboxylate group (COO), R₂ is either hydrogen or an organic group, and R₃ is either hydrogen or an organic group.

17. The method of claim 1, wherein pH of the first processing fluid is substantially equal to pH of the second processing fluid.

18. The method of claim 1, wherein the metal cation is selected from the group consisting of copper ion, gold ion, tin ion, silver ion, platinum ion, ruthenium ion, rhodium ion, iridium ion, osmium ion, rhenium ion, palladium ion, and nickel ion.

19. The method of claim 1, wherein the second processing fluid has a pH greater than 7.0.

20. The method of claim 3, wherein the ion permeable barrier is a cation permeable barrier.

21. The method of claim 20, wherein the cation of the first processing fluid is a metal cation, and further comprising the step of electrolytically depositing the metal cation onto the acid treated surface.

22. The method of claim 21, wherein the second processing fluid further includes cationic species and the process further comprises the step of passing the cationic species from the second processing fluid to the first processing fluid through the cation permeable barrier.

23. The method of claim 1, wherein the acid solution used in the contacting step comprises nitric acid.

24. The method of claim 1, wherein the acid solution is an aqueous solution containing less than about 3 weight % acid.

25. The method of claim 1, wherein the acid solution used in the contacting step comprises hydrofluoric acid.

26. The method of claim 1, wherein the acid solution used in the contacting step comprises nitric acid and hydrofluoric acid.

27. The method of claim 1, wherein the contacting step further comprises contacting a portion of the acid treated surface with a first processing fluid that includes a plurality of species of the cation, the species of the cation having differing deposition potentials.

28. The method of claim 1, wherein the contacting step further comprises contacting a portion of the acid treated surface with a first processing fluid that includes an additive that promotes nucleation of the cation on the treated surface.

29. A method for forming a metallized feature on a surface of a microelectronic workpiece, comprising steps for:
providing a microelectronic workpiece including a barrier layer;
contacting a surface of the barrier layer with an electrolyte solution;
applying electrical power to the barrier layer and an electrode in contact with the electrolyte solution to produce an electrolytically treated surface of the barrier layer without depositing metal onto the barrier layer;
contacting a portion of the electrolytically treated surface of the barrier layer with a first processing fluid, the first processing fluid comprising first processing fluid species including a cation, an anion, and a complexing agent;
contacting a counter electrode with a second processing fluid;
producing an electrochemical reaction at the counter electrode; and
substantially preventing movement of ionic species between the first processing fluid and the second processing fluid species.

30. The method of claim 29, wherein the step of substantially preventing movement of ionic species between the first processing fluid and the second processing fluid comprises providing an ion permeable barrier between the first processing fluid and the second processing fluid.

31. The method of claim 29, wherein the ion permeable barrier is an anion permeable barrier.

32. The method of claim 31, wherein the cation of the first processing fluid is a metal cation, and further comprising the step of electrolytically depositing the metal cation onto the electrolytically treated surface of the barrier layer.

33. The method of claim 32, wherein the first processing fluid further includes a counter anion of the metal cation and the process further comprises the step of passing the counter anion from the first processing fluid to the second processing fluid through the anion permeable barrier.

34. The method of claim 29, wherein the counter electrode is an inert anode.

35. The method of claim 29, wherein the counter electrode is a consumable anode.

36. The method of claim 29, wherein the first processing fluid has a pH greater than 7.0.

37. The method of claim 29, further comprising the step of adding a metal cation to the first processing fluid.

38. The method of claim 29, wherein the first processing fluid species further include a pH adjustment agent and a buffer.

39. The method of claim 29, wherein the second processing fluid comprises a pH adjustment agent and a buffer.

40. The method of claim 39, wherein buffer concentration in the first processing fluid is equal to or less than buffer concentration in the second processing fluid.

41. The method of claim 29, wherein the complexing agent is selected from the group consisting of ethylene diamine, ethylene diamine tetraacetic acid and its salts, cyclam, porphrin, bipyridyl, pyrolle, thiophene, and polyamines.

42. The method of claim 29, wherein the complexing agent is selected from compounds that contain a nitrogen-containing chelating group R—NR₂—R₁, where R is any alkyl group, aromatic group, or polymer chain and R₁ and R₂ are H, alkyl or aryl organic groups.

43. The method claim 29, wherein the complexing agent includes chemical compounds having at least one part with the chemical structure COOR₁—COHR₂R₃ where R₁ is an organic group or hydrogen covalently bound to the carboxylate group (COO), R₂ is either hydrogen or an organic group, and R₃ is either hydrogen or an organic group.

44. The method of claim 29, wherein pH of the first processing fluid is substantially equal to pH of the second processing fluid.

45. The method of claim 29, wherein the metal cation is selected from the group consisting of copper ion, gold ion, tin ion, silver ion, platinum ion, ruthenium ion, rhodium ion, iridium ion, osmium ion, rhenium ion, palladium ion, and nickel ion.

46. The method of claim 29, wherein the second processing fluid has a pH greater than 7.0.

47. The method of claim 30, wherein the ion permeable barrier is a cation permeable barrier.

48. The method of claim 47, wherein the cation of the first processing fluid is a metal cation, and further comprising the step of electrolytically depositing the metal cation onto the electrolytically treated surface of the barrier layer.

49. The method of claim 48, wherein the second processing fluid further includes cationic species and the process further comprises the step of passing the cationic species from the second processing fluid to the first processing fluid through the cation permeable barrier.

50. The method of claim 29, wherein the contacting step further comprises contacting a portion of the acid treated surface with a first processing fluid that includes a plurality of species of the cation, the species of the cation having differing deposition potentials.

51. The method of claim 29, wherein the contacting step further comprises contacting a portion of the acid treated surface with a first processing fluid that includes an additive that promotes nucleation of the cation on the treated surface.

52. A method for forming a metallized feature on a surface of a microelectronic workpiece, comprising steps for:
providing a microelectronic workpiece including a barrier layer;
electrochemically depositing a metal alloy onto the barrier layer;
contacting a portion of the metal alloy deposited onto the barrier layer with a first processing fluid, the first processing fluid comprising first processing fluid species including a cation, an anion, and a complexing agent;
contacting a counter electrode with a second processing fluid;
producing an electrochemical reaction at the counter electrode; and
substantially preventing movement of ionic species between the first processing fluid and the second processing fluid species.

53. The method of claim 52, wherein the metal alloy is a copper alloy.

54. The method of claim 52, wherein the copper alloy includes copper as a first metal and a second metal selected from the group consisting of chromium, nickel, cobalt, zinc, aluminum, boron, magnesium, and cerium.

55. The method of claim 52, wherein the composition of the metal alloy is constant throughout its thickness.

56. The method of claim 52, wherein the composition of the metal alloy varies throughout its thickness.

57. The method of claim 52, wherein the step of substantially preventing movement of ionic species between the first processing fluid and the second processing fluid comprises providing an ion permeable barrier between the first processing fluid and the second processing fluid.

58. The method of claim 57, wherein the ion permeable barrier is an anion permeable barrier.

59. The method of claim 58, wherein the cation of the first processing fluid is a metal cation, and further comprising the step of electrolytically depositing the metal cation onto a portion of the metal alloy.

60. The method of claim 59, wherein the first processing fluid further includes a counter anion of the metal cation and the process further comprises the step of passing the counter anion from the first processing fluid to the second processing fluid through the anion permeable barrier.

61. The method of claim 52, wherein the counter electrode is an inert anode.

62. The method of claim 52, wherein the counter electrode is a consumable anode.

63. The method of claim 52, wherein the first processing fluid has a pH greater than 7.0.

64. The method of claim 52, further comprising the step of adding a metal ion to the first processing fluid.

65. The method of claim 52, wherein the first processing fluid species further include a pH adjustment agent and a buffer.

66. The method of claim 65, wherein the second processing fluid comprises a pH adjustment agent and a buffer.

67. The method of claim 66, wherein buffer concentration in the first processing fluid is equal to or less than buffer concentration in the second processing fluid.

68. The method of claim 52, wherein the complexing agent is selected from the group consisting of ethylene diamine, ethylene diamine tetraacetic acid and its salts, cyclam, porphrin, bipyridyl, pyrolle, thiophene, and polyamines.

69. The method of claim 52, wherein the complexing agent is selected from compounds that contain a nitrogen-containing chelating group R—NR₂—R₁, where R is any alkyl group, aromatic group, or polymer chain, and R₁ and R₂ are H, alkyl or aryl organic groups.

70. The method claim 52, wherein the complexing agent includes chemical compounds having at least one part with the chemical structure COOR₁—COHR₂R₃ where R₁ is an organic group, a hydrogen covalently bound to the carboxylate group (COO), R₂ is either hydrogen or an organic group, and R₃ is either hydrogen or an organic group.

71. The method of claim 52, wherein pH of the first processing fluid is substantially equal to pH of the second processing fluid.

72. The method of claim 52, wherein the cation is selected from the group consisting of copper ion, gold ion, tin ion, silver ion, platinum ion, ruthenium ion, rhodium ion, iridium ion, osmium ion, rhenium ion, palladium ion, and nickel ion.

73. The method of claim 52, wherein the second processing fluid has a pH greater than 7.0.

74. The method of claim 57, wherein the ion permeable barrier is a cation permeable barrier.

75. The method of claim 74, wherein the cation of the first processing fluid is a metal ion, and further comprising the step of electrolytically depositing the metal ion onto a portion of the metal alloy.

76. The method of claim 75, wherein the second processing fluid further includes cationic species and the process further comprises the step of passing the cationic species from the second processing fluid to the first processing fluid through the cation permeable barrier.

77. The method of claim 52, wherein the contacting step further comprises contacting a portion of the acid treated surface with a first processing fluid that includes a plurality of species of the cation, the species of the cation having differing deposition potentials.

78. The method of claim 52, wherein the contacting step further comprises contacting a portion of the acid treated surface with a first processing fluid that includes an additive that promotes nucleation of the cation on the treated surface.
